(19) United States
(12) Patent Application Publication
(10) Pub. No.: US 2024/0258354 A1
(43) Pub. Date: Aug. 1, 2024

(54) IMAGE SENSOR AND ELECTRONIC SYSTEM INCLUDING THE SAME

(71) Applicant: Samsung Electronics Co., Ltd., Suwon-si (KR)

(72) Inventors: Jungsan Kim, Suwon-si (KR); Kwansik Kim, Suwon-si (KR); Jinyong Choi, Suwon-si (KR); Gayoung Kim, Suwon-si (KR); Taemin Kim, Suwon-si (KR); Yongsoon Park, Suwon-si (KR); Ingyu Baek, Suwon-si (KR); Seungho Lee, Suwon-si (KR)

(21) Appl. No.: 18/242,597

(22) Filed: Sep. 6, 2023

(30) Foreign Application Priority Data
Jan. 31, 2023 (KR) 10-2023-0013184

(51) Int. Cl. H01L 27/146

(52) U.S. Cl. CPC H01L 27/14632; H01L 27/14603; H01L 27/14645

(57) ABSTRACT

An image sensor includes a lower insulating film arranged over a substrate and having a non-flat surface that has a concave-convex shape and includes a first surface, which extends in a horizontal direction parallel to a frontside surface of the substrate, and at least one second surface extending from the first surface toward the substrate, a capacitor arranged on the lower insulating film to contact the non-flat surface of the lower insulating film and conformally covering the non-flat surface of the lower insulating film along the contour of the non-flat surface of the lower insulating film, an upper insulating film covering the capacitor and the lower insulating film, and at least one air gap having a side facing the at least one second surface of the lower insulating film in the horizontal direction and having a height defined by the upper insulating film in a vertical direction.

### CROSS-REFERENCE TO RELATED APPLICATION

This application is based on and claims priority under 35 U.S.C. § 119 to Korean Patent Application No. 10-2023-0013184, filed on Jan. 31, 2023, in the Korean Intellectual Property Office, the disclosure of which is incorporated by reference herein in its entirety.

### BACKGROUND

The inventive concept relates to an image sensor and an electronic system including the image sensor, and more particularly, to an image sensor, which includes a capacitor, and an electronic system including the image sensor.

Along with the advance of the computer industry and the communication industry, image sensors, which capture images and convert the images into electrical signals, are used in various applications, such as digital cameras, camcorders, personal communication systems (PCSs), game consoles, security cameras, and medical micro-cameras. Along with highly integrating image sensors and making pixel sizes finer, it is important for image sensors including capacitors to secure stable electrical characteristics.

### SUMMARY

Aspects of the inventive concept provide an image sensor including a capacitor having a structure, which allows the capacitance per unit area to be increased by increasing the effective area thereof and allows unintended coupling capacitance between the capacitor and conductors therearound to be reduced.

Aspects of the inventive concept also provide an electronic system including a capacitor having a structure, which allows the capacitance per unit area to be increased by increasing the effective area thereof and allows unintended coupling capacitance between the capacitor and conductors therearound to be reduced.

According to an aspect of the inventive concept, an image sensor includes a lower insulating film arranged over a substrate and having a non-flat surface that has a concave-convex shape and includes a first surface, which extends in a horizontal direction parallel to a frontside surface of the substrate, and at least one second surface extending from the first surface toward the substrate, a capacitor arranged on the lower insulating film to contact the non-flat surface of the lower insulating film and conformally covering the non-flat surface of the lower insulating film along the contour of the non-flat surface of the lower insulating film, an upper insulating film covering the capacitor and the lower insulating film, and at least one air gap having a side facing the at least one second surface of the lower insulating film in the horizontal direction and having a height defined by the upper insulating film in a vertical direction.

According to another aspect of the inventive concept, an image sensor includes a plurality of lower wiring patterns over a substrate, a lower insulating film covering the plurality of lower wiring patterns and having a surface that has a concave-convex shape and includes a first surface extending in at least one of a first horizontal direction and a second horizontal direction, which are parallel to a frontside surface of the substrate, and at least one second surface extending from the first surface toward the substrate, at least one capacitor arranged on the lower insulating film to contact the surface of the lower insulating film and conformally covering the surface of the lower insulating film along the contour of the concave-convex shape of the surface of the lower insulating film, an upper insulating film covering the at least one capacitor and the lower insulating film, at least one air gap adjacent to the at least one second surface of the lower insulating film in the first horizontal direction or the second horizontal direction and having a height defined by the upper insulating film in a vertical direction, a plurality of upper wiring patterns on the upper insulating film, and a first via contact and a second via contact, each passing through a portion of the at least one capacitor, which covers the first surface of the lower insulating film, in the vertical direction and each connected between one of the plurality of lower wiring patterns and one of the plurality of upper wiring patterns, the first via contact and the second via contact being spaced apart from each other in the second horizontal direction.

According to yet another aspect of the inventive concept, an electronic system includes at least one camera module including an image sensor, and a processor configured to process image data received from the at least one camera module, wherein the image sensor includes a lower insulating film arranged over a substrate and having a surface that has a concave-convex shape and includes a first surface, which extends in a horizontal direction parallel to a frontside surface of the substrate, and at least one second surface extending from the first surface toward the substrate, a capacitor arranged on the lower insulating film to contact the surface of the lower insulating film and conformally covering the surface of the lower insulating film along the contour of the concave-convex shape of the surface of the lower insulating film, an upper insulating film covering the capacitor and the lower insulating film, and at least one air gap having a side facing the at least one second surface of the lower insulating film in the horizontal direction and formed in the upper insulating film.

### BRIEF DESCRIPTION OF THE DRAWINGS

Embodiments will be more clearly understood from the following detailed description taken in conjunction with the accompanying drawings in which:

FIG. 1 is a block diagram illustrating an image sensor according to some embodiments;

FIG. 2 is a planar layout diagram illustrating some components of a pixel array, which is included in the image sensor shown in FIG. 1; FIG. 3A is a cross-sectional view of a portion of the pixel array, taken along a line X1-X1′ of FIG. 2; FIG. 3B is a cross-sectional view of a portion of the pixel array, taken along a line Y1-Y1′ of FIG. 2; FIG. 3C is an enlarged cross-sectional view of a region EX1 of FIG. 3B;

FIGS. 4A and 4B are cross-sectional views illustrating an image sensor according to some embodiments;

FIG. 5 is a cross-sectional view illustrating an image sensor according to some embodiments;

FIGS. 6A and 6B are cross-sectional views illustrating an image sensor according to some embodiments;

FIG. 7 is a cross-sectional view illustrating an image sensor according to some embodiments;

FIGS. 8A and 8B are cross-sectional views illustrating an image sensor according to some embodiments;

FIG. 9 is a cross-sectional view illustrating an image sensor according to some embodiments;

FIGS. 10A and 10B are planar layout diagrams illustrating some components of a pixel array, which is included in an image sensor according to some embodiments;

FIG. 11A is a layout diagram of an image sensor according to some embodiments; FIG. 11B is a cross-sectional view of the image sensor, taken along a line X1-X1′ of FIG. 11A; FIG. 11C is a cross-sectional view of the image sensor, taken along a line Y1-Y1′ of FIG. 11B;

FIGS. 12A to 12D are cross-sectional views respectively illustrating a sequence of processes of an example method of fabricating a capacitor of an image sensor, according to some embodiments;

FIGS. 13A to 13F are cross-sectional views respectively illustrating a sequence of processes of an example method of fabricating a capacitor of an image sensor, according to some embodiments;

FIGS. 14A to 21B are cross-sectional views respectively illustrating a sequence of processes of an example of a method of fabricating an image sensor, according to some embodiments, and in particular, FIGS. 14A to 21A respectively illustrate cross-sectional views of the image sensor, which correspond to a cross-section taken along the line X1-X1′ of FIG. 11A, according to the sequence of processes, and FIGS. 14B to 21B respectively illustrate cross-sectional views of the image sensor, which correspond to a cross-section taken along the line Y1-Y1′ of FIG. 11A, according to the sequence of processes; and

FIG. 22A is a block diagram of an electronic system according to some embodiments, and FIG. 22B is a detailed block diagram of a camera module included in the electronic system of FIG. 22A, according to an embodiment.

### DETAILED DESCRIPTION OF THE EMBODIMENTS

Hereinafter, embodiments of the inventive concept will be described in detail with reference to the accompanying drawings. Like components are denoted by like reference numerals throughout the specification, and repeated descriptions thereof are omitted.

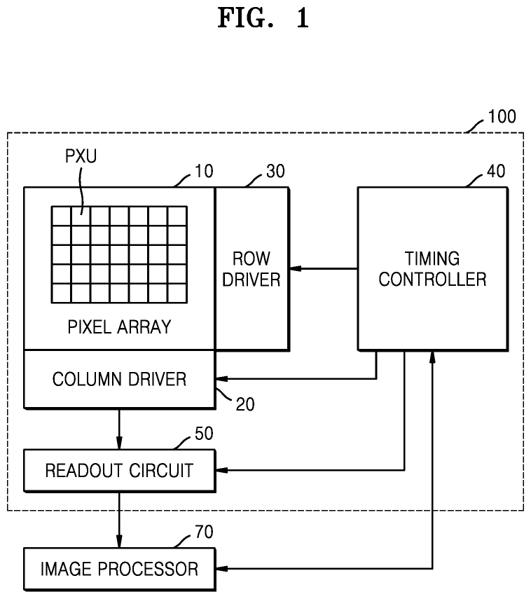

FIG. 1 is a block diagram illustrating an image sensor according to some embodiments.

Referring to FIG. 1, an image sensor 100 according to some embodiments may include a pixel array 10 and circuits for controlling the pixel array 10. In some embodiments, the circuits for controlling the pixel array 10 may include a column driver 20, a row driver 30, a timing controller 40, and a readout circuit 50.

The image sensor 100 may operate according to a control command received from an image processor 70 and may convert light transferred from an external object into an electrical signal and output the electrical signal to the image processor 70. The image sensor 100 may include or be a complementary metal-oxide-semiconductor (CMOS) image sensor.

The pixel array 10 may include a plurality of unit pixels PXU, which have a 2-dimensional array structure and are arranged in a matrix form along a plurality of row lines and a plurality of column lines.

Each of the plurality of unit pixels PXU may include a photodiode. The photodiode may receive light transferred from the object and thus generate charges. The image sensor 100 may perform an autofocus function by using phase differences between pixel signals respectively generated by a plurality of photodiodes in the plurality of unit pixels PXU. Each of the plurality of unit pixels PXU may include a pixel circuit for generating a pixel signal from charges generated by the photodiode.

In some embodiments, the image sensor 100 may include an image sensor capable of performing a global shutter operation. For example, during the operation of the image sensor 100, all the unit pixels PXU in the pixel array 10 may be simultaneously exposed to an optical signal provided from outside the image sensor 100, and thus, charges may be simultaneously stored in each of the plurality of unit pixels PXU. In some embodiments, pixel signals due to the charges stored in each of the plurality of unit pixels PXU may be sequentially output by row.

The column driver 20 may include a correlated double sampler (CDS), an analog-to-digital converter (ADC), and the like. The CDS may be connected with unit pixels PXU, which are included in a row selected by a row select signal provided by the row driver 30, via column lines and may detect a reset voltage and a pixel voltage by performing correlated double sampling. The ADC may convert the reset voltage and the pixel voltage, which are detected by the CDS, into a digital signal and transfer the digital signal to the readout circuit 50.

The readout circuit 50 may include a latch or a buffer circuit, which may temporarily store the digital signal, an amplifier circuit, and the like and may generate image data by temporarily storing or amplifying the digital signal received from the column driver 20. Operation timings of the column driver 20, the row driver 30, and the readout circuit 50 may be determined by the timing controller 40, and the timing controller 40 may be operated by a control command transmitted by the image processor 70.

The image processor 70 may perform signal processing on the image data, which is output by the readout circuit 50, and output the processed image data to a display device or store the processed image data in a storage device, such as memory. When the image sensor 100 is mounted on an autonomous vehicle, the image processor 70 may perform signal processing on the image data and transmit the processed image data to a main controller for controlling the autonomous vehicle or the like.

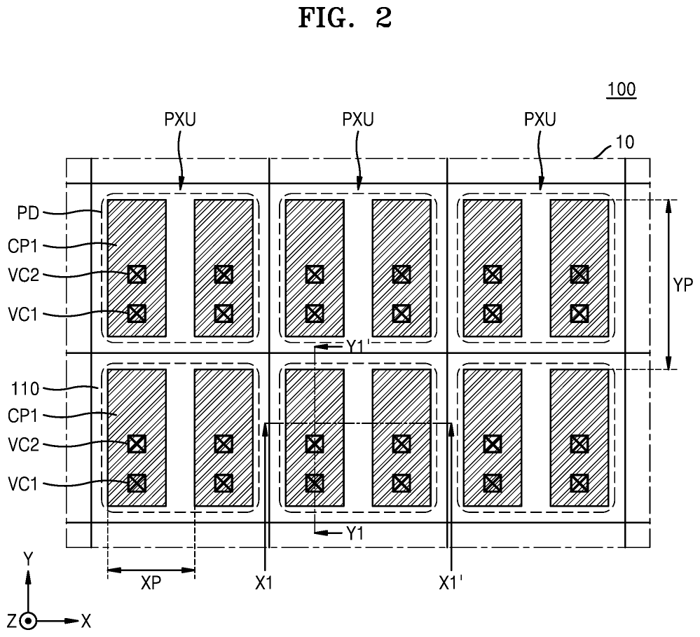

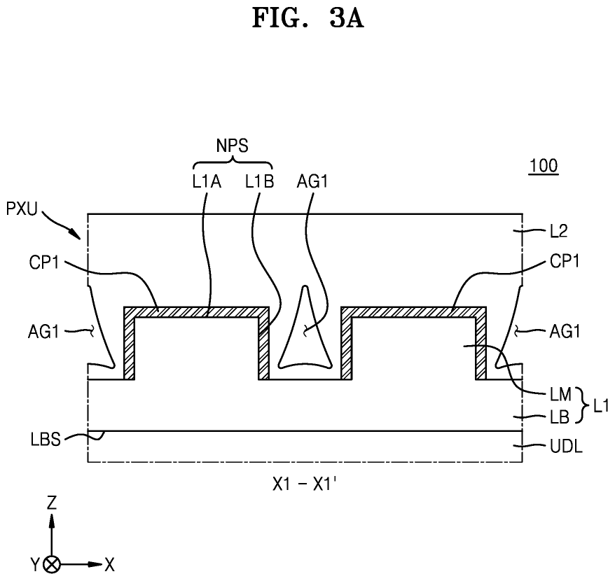

FIG. 2 is a planar layout diagram illustrating some components of the pixel array 10, which is included in the image sensor 100 shown in FIG. 1. FIG. 3A is a cross-sectional view of a portion of the pixel array 10, taken along a line X1-X1′ of FIG. 2. FIG. 3B is a cross-sectional view of a portion of the pixel array 10, taken along a line Y1-Y1′ of FIG. 2. FIG. 3C is an enlarged cross-sectional view of a region EX1 of FIG. 3B.

Referring to FIGS. 2 and 3A to 3C, the pixel array 10 of the image sensor 100 may include a plurality of unit pixels PXU, which are repeatedly arranged in a first horizontal direction (X direction) and a second horizontal direction (Y direction) to form a matrix-formed arrangement and thus have a 2-dimensional array structure. The plurality of unit pixels PXU may respectively include a plurality of photodiodes PD arranged in a substrate 110, and may include a plurality of capacitors CP1 arranged on the substrate 110 and respectively overlapping the plurality of photodiodes PD in the vertical direction (Z direction). The plurality of capacitors CP1 may be arranged at regular pitches in the first horizontal direction (X direction) and the second horizontal direction (Y direction) over the substrate 110. As shown in FIG. 2, the plurality of capacitors CP1 may be repeatedly arranged with a first pitch XP in the first horizontal direction (X direction) and repeatedly arranged with a second pitch YP in the second horizontal direction (Y direction).

Two capacitors CP1 adjacent to each other in the first horizontal direction (X direction) from among the plurality of capacitors CP1 may overlap one photodiode PD selected from the plurality of photodiodes PD in the vertical direction (Z direction). The two capacitors CP1 overlapping the one photodiode PD in the vertical direction (Z direction) may be apart from each other in the first horizontal direction (X direction).

As shown in FIG. 3B, each of the plurality of capacitors CP1 may be arranged between a plurality of lower wiring patterns ML and a plurality of upper wiring patterns MU. The plurality of lower wiring patterns ML may pass through a lower interlayer dielectric UDL in the vertical direction (Z direction). The plurality of lower wiring patterns ML and the lower interlayer dielectric UDL may be covered by a lower insulating film L1, and the plurality of capacitors CP1 may be arranged on the lower insulating film L1.

As shown in FIGS. 3A and 3B, the lower insulating film L1 may include a base portion LB and a plurality of mesa portions LM, which are integrally connected to each other (e.g., integrally formed as a single unitary structure). The plurality of mesa portions LM may each include a portion protruding in the vertical direction (Z direction) from the base portion LB. In the vertical direction (Z direction), the thickness of each of the plurality of mesa portions LM of the lower insulating film L1 may be greater than the thickness of the base portion LB of the lower insulating film L1. In some embodiments, a difference H1 between a vertical level of an upper surface of a mesa portion LM and a vertical level of an upper surface of the base portion LB in the vertical direction (Z direction), may be, but is not limited to, about 50 nm to about 250 nm, for example, about 100 nm to about 200 nm.

The mesa portion LM of the lower insulating film L1 may include surfaces extending in directions intersecting with each other such that stepped portions are formed in the lower insulating film L1. For example, an upper surface L1A of the mesa portion LM may extend flat in the first horizontal direction (X direction) and the second horizontal direction (Y direction) that are parallel to a frontside surface of the substrate 110, which faces a capacitor CP1, and a sidewall LIB of the mesa portion LM may extend from the upper surface L1A of the mesa portion LM toward the substrate 110 or the base portion LB of the lower insulating film L1. The upper surface L1A and the sidewall LIB of the mesa portion LM may provide a non-flat surface NPS of a concave-convex shape to the lower insulating film L1. Herein, the upper surface L1A (e.g., top surface) of the mesa portion LM may be referred to as a first surface and the sidewall LIB of the mesa portion LM may be referred to as a second surface or side surface. A lower surface LBS (e.g., bottom surface) of the lower insulating film L1 may be in contact with the lower interlayer dielectric UDL.

Ordinal numbers such as “first,” “second,” “third,” etc., may be used simply as labels of certain elements, directions, steps, etc., to distinguish such elements, directions, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

The plurality of capacitors CP1 may be arranged on the lower insulating film L1. Each of the plurality of capacitors CP1 may be in contact with the upper surface L1A and the sidewall LIB of the mesa portion LM, which are included in the non-flat surface NPS of the lower insulating film L1. Each of the plurality of capacitors CP1 may conformally cover the non-flat surface NPS of the lower insulating film L1 along the contour of the non-flat surface NPS of the lower insulating film L1. The non-flat surface may also be described as a humped surface.

The plurality of capacitors CP1 and the lower insulating film L1 may be covered by an upper insulating film L2. A plurality of air gaps AG may be included in the upper insulating film L2. Each of the plurality of air gaps AG1 may have a side facing the sidewall LIB of the mesa portion LM in the first horizontal direction (X direction) or the second horizontal direction (Y direction). Therefore, air gaps may be formed between sides of two adjacent capacitors in the first horizontal direction (X direction) and air gaps may be formed between sides of two adjacent capacitors in the second horizontal direction (Y direction). The size of each of the plurality of air gaps AG1 in the vertical direction (Z direction) may be defined by the upper insulating film L2. For example, when forming the upper insulating film L2 (described further below), an air gap AG1 may be formed in the film and may have a height that forms a shape that remains at the completion of the forming process. For example, each air gap AG1, and other air gaps described herein, may have a shape that tapers (e.g., narrows) in a direction away from the lower interlayer dielectric layer UDL. As used herein, the term “air” may refer to the atmosphere or to other gases that may be present during a fabrication process. Each of the plurality of air gaps AG1 may include atmospheric gases or other gases that may be present during a fabrication process.

One air gap AG1 may be arranged between each two capacitors CP1 from among the plurality of capacitors CP1 in the first horizontal direction (X direction) and one air gap AG1 may be arranged between each two capacitors CP1 from among the plurality of capacitors CP1 the second horizontal direction (Y direction). That is, two capacitors CP1, which are adjacent to each other in the first horizontal direction (X direction), from among the plurality of capacitors CP1 may be apart from each other with one air gap AG1 therebetween, and two capacitors CP1, which are adjacent to each other in the second horizontal direction (Y direction), from among the plurality of capacitors CP1 may be apart from each other with one air gap AG1 therebetween. Items described as apart from each other are spaced apart from each other (e.g., physically separated) with some other component (e.g., air or gas, or a solid material) therebetween. The mesa portion LM of the lower insulating film L1 may be apart from an air gap AG1 in the first horizontal direction (X direction) or the second horizontal direction (Y direction) with the capacitor CP1 therebetween.

The plurality of upper wiring patterns MU may be arranged on the upper insulating film L2. The plurality of upper wiring patterns MU may each have various cross-sectional shapes. For example, some of the plurality of upper wiring patterns MU may have lower surfaces contacting an upper surface of the upper insulating film L2. Some other upper wiring patterns MU may have lower surfaces at a vertical level that is closer to the capacitor CP1 than it is to a vertical level of the upper surface of the upper insulating film L2, as a result of being formed by a dual damascene process.

In some embodiments, the plurality of lower wiring patterns ML and the plurality of upper wiring patterns MU may each include a metal plug and a conductive barrier film surrounding the metal plug. The metal plug may include or be, but is not limited to, copper (Cu), tungsten (W), cobalt (Co), or a combination thereof. The conductive barrier film may include or be, but is not limited to, TaN. In some embodiments, each of the lower interlayer dielectric UDL, the lower insulating film L1, and the upper insulating film L2 may include or be a silicon oxide film, a silicon nitride film, an SiCN film, an SiON film, an SiOC film, an SiOCN film, or a combination thereof. For example, each of the lower interlayer dielectric UDL, the lower insulating film L1, and the upper insulating film L2 may include or be a tetraethylorthosilicate (TEOS) oxide film.

The image sensor 100 may include a plurality of first via contacts VC1 and a plurality of second via contacts VC2. The plurality of first via contacts VC1 and the plurality of second via contacts VC2 may each pass through one capacitor CP1 selected from the plurality of capacitors CP1 in the vertical direction (Z direction). As shown in FIGS. 2, 3B, and 3C, each of the plurality of capacitors CP1 may include a flat portion extending flat along the upper surface L1A of the mesa portion LM, and one first via contact VC1 and one second via contact VC2 may pass through the flat portion of each of the plurality of capacitors CP1 in the vertical direction (Z direction).

Each of the first via contact VC1 and the second via contact VC2 may pass through the upper insulating film L2, the capacitor CP1, and the lower insulating film L1 in the vertical direction (Z direction) and thus be connected between one of the plurality of lower wiring patterns ML and one of the plurality of upper wiring patterns MU. The first via contact VC1 and the second via contact VC2, which pass through one capacitor CP1, may be apart from each other in the second horizontal direction (Y direction).

Each of the first via contact VC1 and the second via contact VC2 may be apart from the sidewall LIB of the mesa portion LM in the first horizontal direction (X direction) and/or the second horizontal direction (Y direction) to pass through the flat portion of the capacitor CP1 in the vertical direction (Z direction).

In some embodiments, each contact of the plurality of first via contacts VC1 and the plurality of second via contacts VC2 may include or be formed of a metal plug and a conductive barrier film surrounding the metal plug. The metal plug may include or be, but is not limited to, copper (Cu), tungsten (W), cobalt (Co), or a combination thereof. The conductive barrier film may include or be, but is not limited to, TaN.

As shown in FIG. 3C, each of the plurality of capacitors CP1 may include a metal-insulator-metal (MIM) capacitor, which includes a plurality of electrode plates sequentially stacked on the mesa portion LM of the lower insulating film L1. The plurality of electrode plates may include a lower electrode plate P1, an upper electrode plate P3, and an intermediate electrode plate MP2. The intermediate electrode plate MP2 may be arranged between the lower electrode plate P1 and the upper electrode plate P3. In addition, each of the plurality of capacitors CP1 may include a plurality of dielectric films D1 and D2 respectively arranged between electrode plates adjacent to each other from among the lower electrode plate P1, the upper electrode plate P3, and the intermediate electrode plate MP2, such that the lower electrode plate P1, the upper electrode plate P3, and the intermediate electrode plate MP2 are apart from each other and electrically insulated from each other at their top and bottom surfaces.

The first via contact VC1 may be in contact with, and therefore electrically connected to, the intermediate electrode plate MP2 and may be apart from, and therefore electrically insulated from the lower electrode plate P1 and the upper electrode plate P3. The second via contact VC2 may be in contact with, and therefore electrically connected to, the lower electrode plate P1 and the upper electrode plate P3 and may be apart from, and therefore electrically insulated from, the intermediate electrode plate MP2.

In some embodiments, each of the lower electrode plate P1, the upper electrode plate P3, and the intermediate electrode plate MP2 may be or include a metal, a conductive metal nitride, or a combination thereof. For example, each of the lower electrode plate P1, the upper electrode plate P3, and the intermediate electrode plate MP2 may include or may be, but is not limited to, TiN. In some embodiments, each of the lower electrode plate P1, the upper electrode plate P3, and the intermediate electrode plate MP2 may have, but is not limited to, a thickness of about 10 nm to about 100 nm, for example, about 30 nm to about 50 nm.

In some embodiments, each of the plurality of dielectric films D1 and D2 may include or may be, but is not limited to, a silicon oxide film, a high-K film having a dielectric constant that is greater than that of a silicon oxide film, or a combination thereof. The high-K film may have a dielectric constant of about 10 to about 25. The high-K film may be or include, but is not limited to, a hafnium oxide film, an aluminum oxide film, a zirconium oxide film, a hafnium silicon oxide film, a hafnium zirconium oxide film, a titanium oxide film, a tantalum oxide film, or a combination thereof. For example, each of the plurality of dielectric films D1 and D2 may have a triple-layered structure of hafnium oxide film/aluminum oxide film/hafnium oxide film. In some embodiments, each of the plurality of dielectric films D1 and D2 may have, but is not limited to, a thickness of about 1 nm to about 20 nm, for example, about 2 nm to about 10 nm.

Because the image sensor 100 includes the plurality of capacitors CP1 conformally covering the non-flat surface NPS of the lower insulating film L1, each of the plurality of capacitors CP1 may have an increased effective area and thus have increased capacitance per unit area. In addition, because the image sensor 100 includes the plurality of air gaps AG1 arranged in the upper insulating film L2 around each of the plurality of capacitors CP1, unintended coupling capacitance between the plurality of capacitors CP1 and the plurality of upper wiring patterns MU may be reduced and the stress in the upper insulating film L2, which is arranged between the plurality of capacitors CP1 and the plurality of upper wiring patterns MU, may be alleviated, thereby preventing defects due to an unintended excess of stress. Therefore, the reliability of the image sensor 100 may improve.

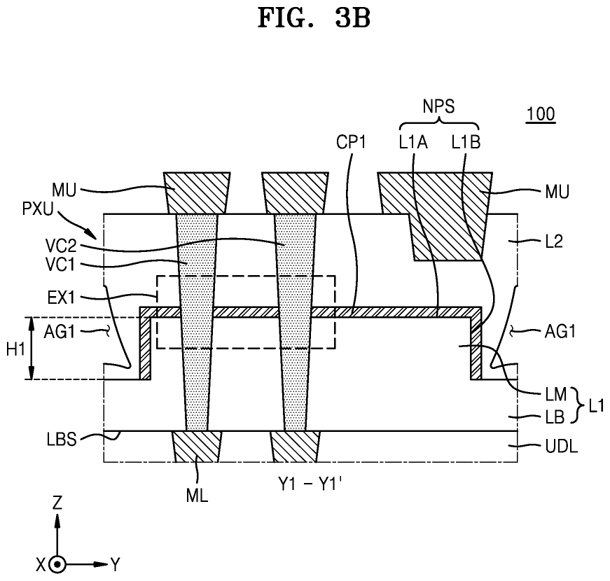

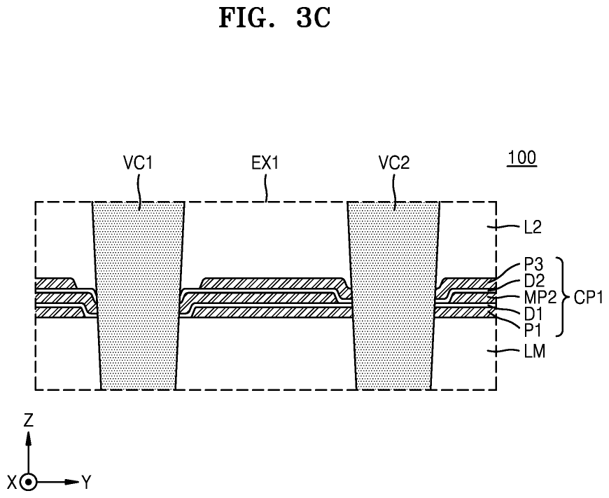

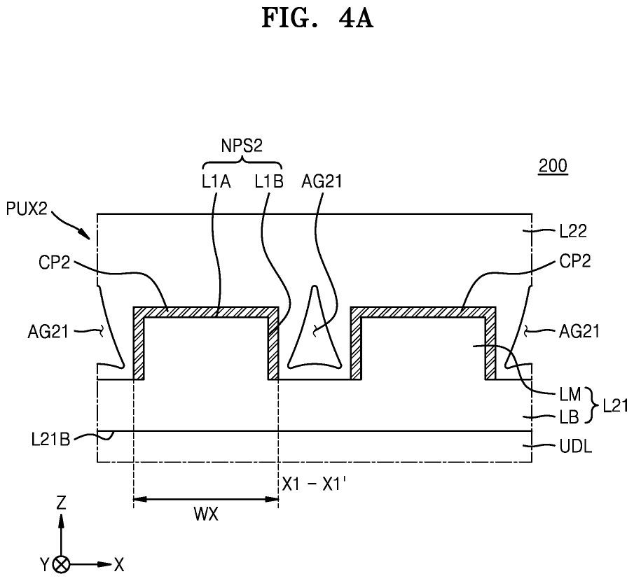

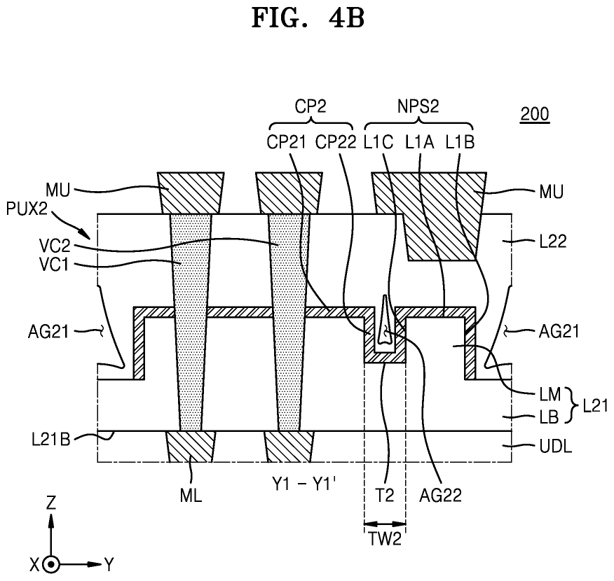

FIGS. 4A and 4B are cross-sectional views illustrating an image sensor 200 according to some embodiments, and in particular, FIG. 4A is a cross-sectional view of a portion of the image sensor 200, which corresponds to the cross-section taken along the line X1-X1′ of FIG. 2, and FIG. 4B is a cross-sectional view of a portion of the image sensor 200, which corresponds to the cross-section taken along the line Y1-Y1′ of FIG. 2. In FIGS. 4A and 4B, the same reference numerals as in FIGS. 2 and 3A to 3C respectively denote the same members, and here, repeated descriptions thereof are omitted.

Referring to FIGS. 4A and 4B, the image sensor 200 may have mostly the same configuration as the image sensor 100 described with reference to FIGS. 2 and 3A to 3C. Similar to the description made with reference to FIG. 2, the image sensor 200 may include a plurality of unit pixels PXU2, which are repeatedly arranged in the first horizontal direction (X direction) and the second horizontal direction (Y direction) to form a matrix-formed arrangement and thus have a 2-dimensional array structure. The plurality of unit pixels PXU2 of the image sensor 200 may have substantially the same configuration as the plurality of unit pixels PXU described with reference to FIGS. 3A to 3C. However, the plurality of unit pixels PXU2 may respectively include a plurality of capacitors CP2.

The plurality of capacitors CP2 have mostly the same configuration as the plurality of capacitors CP1 described with reference to FIGS. 3A to 3C. However, each of the plurality of capacitors CP2 may be arranged on a lower insulating film L21. The lower insulating film L21 includes a base portion LB and a plurality of mesa portions LM, which are integrally connected to each other, and a trench T2 is formed in the upper surface of each of the plurality of mesa portions LM to be recessed toward a lower surface L21B of the lower insulating film L21.

The width of the trench T2 in the first horizontal direction (X direction) may be less than the width of each of the plurality of capacitors CP2 in the first horizontal direction (X direction). In some embodiments, a width WX of each of the plurality of capacitors CP2 in the first horizontal direction (X direction) may be about 800 nm to about 900 nm, and in this case, the width of the trench T2 in the first horizontal direction (X direction) may be about 600 nm to about 800 nm, for example, about 650 nm to about 750 nm (e.g., to be from about 75% to about 90% and in some cases from about 80% to about 85% of the width WX of each capacitor CP2 in the first horizontal direction), but the inventive concept is not limited thereto. A width TW2 of the trench T2 in the second horizontal direction (Y direction) may be, but is not limited to, about 200 nm to about 500 nm, for example, about 300 nm to about 400 nm (e.g., to be from about 25% to about 60% and in some cases from about 35% to about 45% of the width WX of each capacitor CP2 in the first horizontal direction). The trenches described herein may have a particular height, and the air gaps described herein may have a height at least the same as a height of the trench in which they are formed.

Each of the plurality of mesa portions LM of the lower insulating film L21 may include a portion protruding in the vertical direction (Z direction) from the base portion LB. A non-flat surface NPS2 of the lower insulating film L21 may include the upper surface L1A of the mesa portion LM, the sidewall LIB of the mesa portion LM, and an inner sidewall L1C of the trench T2. Herein, the sidewall LIB of the mesa portion LM and the inner sidewall L1C of the trench T2 may each be referred to as a second surface.

Each of the plurality of capacitors CP2 may be in contact with the upper surface L1A and the sidewall LIB of the mesa portion LM and the inner sidewall L1C of the trench T2, which are included in the non-flat surface NPS2 of the lower insulating film L21. Each of the plurality of capacitors CP2 may conformally cover the non-flat surface NPS2 of the lower insulating film L21 along the contour of the non-flat surface NPS2 of the lower insulating film L21. Each of the plurality of capacitors CP2 may include a first portion CP21, which conformally covers the upper surface L1A and the sidewall LIB of the mesa portion LM of the lower insulating film L21, and a second portion CP22 conformally covering inner surfaces of the trench T2, which include the inner sidewall L1C of the trench T2. In some embodiments, as shown in FIG. 4B, in each of the plurality of capacitors CP2, a vertical level of a lowermost surface, which is closest to the lower interlayer dielectric UDL, of the second portion CP22 may be farther from the lower interlayer dielectric UDL than a vertical level of a lowermost surface, which is closest to the lower interlayer dielectric UDL, of the first portion CP21. However, the inventive concept is not limited hereto. For example, unlike the example shown in FIG. 4B, the vertical level of the lowermost surface of the second portion CP22 may be equal to or similar to the vertical level of the lowermost surface of the first portion CP21, or the vertical level of the lowermost surface of the second portion CP22 may be closer to the lower interlayer dielectric UDL than the vertical level of the lowermost surface of the first portion CP21.

A plurality of air gaps may be included in an upper insulating film L22 of the image sensor 200. The plurality of air gaps may include a plurality of first air gaps AG21, which each have sides facing the sidewall LIB of the mesa portion LM in the first horizontal direction (X direction) or the second horizontal direction (Y direction), and a second air gap AG22 having sides facing the inner sidewall L1C of the trench T2 in the second horizontal direction (Y direction), so that the air gap AG22 is adjacent to the inner sidewall L1C of the trench T2 in the second horizontal direction (Y direction). The second air gap AG22 may overlap a capacitor CP2 in the vertical direction (Z direction). The second air gap AG22 may be apart from the inner sidewall L1C of the trench T2 with the capacitor CP2 therebetween.

In the image sensor 200, one first air gap AG21 may be arranged between each two capacitors CP2 from among the plurality of capacitors CP2, and one second air gap AG22 may be arranged above each of the plurality of capacitors CP2 on the non-flat surface NPS2 of the lower insulating film L21. Two capacitors CP2, which are adjacent to each other in the first horizontal direction (X direction) and the second horizontal direction (Y direction), from among the plurality of capacitors CP2 may be apart from each other with one first air gap AG21 therebetween. The size of each of the plurality of first air gaps AG21 and the second air gap AG22 in the vertical direction (Z direction) may be defined by the upper insulating film L22. In the vertical direction (Z direction), the size (e.g., height) of the second air gap AG22 may be less than the size (e.g., height) of each of the plurality of first air gaps AG21.

In the image sensor 200, each of the plurality of capacitors CP2 may include portions through which the first via contact VC1 and the second via contact VC2 respectively pass. The lower insulating film L21 may include a flat portion, which is apart from the non-flat surface NPS2 of the lower insulating film L21 in the second horizontal direction (Y direction) and has a flat upper surface, and the first via contact VC1 and the second via contact VC2 may pass through the capacitor CP2 on the flat portion in the vertical direction (Z direction).

Each of the first via contact VC1 and the second via contact VC2 may pass through the upper insulating film L22, the capacitor CP2, and the lower insulating film L21 in the vertical direction (Z direction) and thus be connected between one of the plurality of lower wiring patterns ML and one of the plurality of upper wiring patterns MU. The first via contact VC1 and the second via contact VC2, which pass through one capacitor CP2, may be apart from each other in the second horizontal direction (Y direction). More detailed configurations of the first via contact VC1 and the second via contact VC2 are the same as described with reference to FIGS. 2, 3B, and 3C.

Because the image sensor 200 includes the plurality of capacitors CP2 conformally covering the non-flat surface NPS2 of the lower insulating film L21, each of the plurality of capacitors CP2 may have an increased effective area and thus have increased capacitance per unit area. In addition, in the image sensor 200, because the plurality of first air gaps AG21 and the second air gap AG22 are arranged in the upper insulating film L22 around each of the plurality of capacitors CP2, unintended coupling capacitance between the plurality of capacitors CP2 and the plurality of upper wiring patterns MU may be reduced and the stress in the upper insulating film L22, which is arranged between the plurality of capacitors CP2 and the plurality of upper wiring patterns MU, may be alleviated, thereby preventing defects due to an unintended excess of stress. Therefore, the reliability of the image sensor 200 may improve.

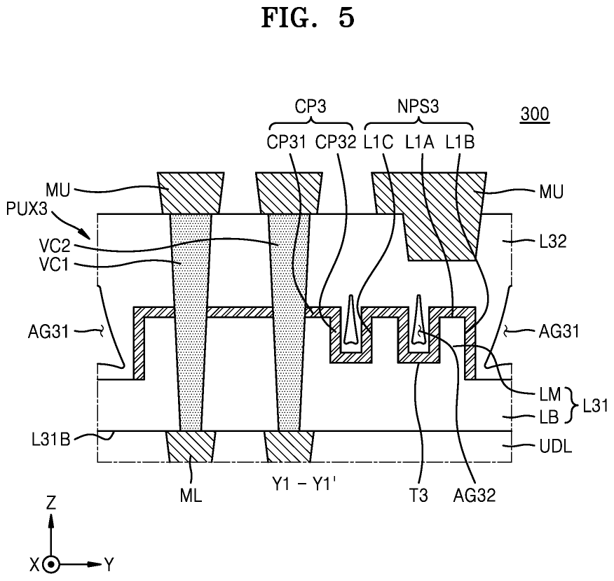

FIG. 5 is a cross-sectional view illustrating an image sensor 300 according to some embodiments. FIG. 5 illustrates a cross-sectional configuration of a portion of the image sensor 300, which corresponds to the cross-section taken along the line Y1-Y1′ of FIG. 2. A cross-sectional configuration of a portion of the image sensor 300, which corresponds to the cross-section taken along the line X1-X1′ of FIG. 2, may be the same as or similar to that described with reference to FIG. 4A. In FIG. 5, the same reference numerals as in FIGS. 2 to 4B respectively denote the same members, and here, repeated descriptions thereof are omitted.

Referring to FIG. 5, the image sensor 300 has mostly the same configuration as the image sensor 200 described with reference to FIGS. 4A and 4B. Similar to the description made with reference to FIG. 2, the image sensor 300 may include a plurality of unit pixels PXU3, which are repeatedly arranged in the first horizontal direction (X direction) and the second horizontal direction (Y direction) to form a matrix-formed arrangement and thus have a 2-dimensional array structure. A unit pixel PXU3 of the image sensor 300 may have mostly the same configuration as the unit pixel PXU2 described with reference to FIGS. 4A and 4B. However, the unit pixel PXU3 includes a capacitor CP3.

The capacitor CP3 may have mostly the same configuration as the capacitor CP2 described with reference to FIGS. 4A and 4B. However, the capacitor CP3 may be arranged on a lower insulating film L31. The lower insulating film L31 includes the base portion LB and the mesa portion LM, which are integrally connected to each other, and a plurality of trenches T3 are formed in the upper surface of the mesa portion LM to be recessed toward a lower surface L31B of the lower insulating film L31. In the second horizontal direction (Y direction), respective widths of the plurality of trenches T3 may be equal to or similar to each other or may be different from each other. In the second horizontal direction (Y direction), the width of each of the plurality of trenches T3 may be, but is not limited to, about 200 nm to about 500 nm, for example, about 300 nm to about 400 nm. A more detailed configuration of each of the plurality of trenches T3 may be the same as that of the trench T2 described with reference to FIGS. 4A and 4B.

The mesa portion LM of the lower insulating film L31 may include a portion protruding in the vertical direction (Z direction) from the base portion LB. A non-flat surface NPS3 of the lower insulating film L31 may include the upper surface L1A of the mesa portion LM, the sidewall LIB of the mesa portion LM, and the inner sidewall L1C of each of the plurality of trenches T3. Herein, the sidewall LIB of the mesa portion LM and the inner sidewall L1C of each of the plurality of trenches T3 may each be referred to as a second surface.

The capacitor CP3 may be in contact with the upper surface L1A and the sidewall LIB of the mesa portion LM and the inner sidewall L1C of each of the plurality of trenches T3, which are included in the non-flat surface NPS3 of the lower insulating film L31. The capacitor CP3 may conformally cover the non-flat surface NPS3 of the lower insulating film L31 along the contour of the non-flat surface NPS3 of the lower insulating film L31. The capacitor CP3 may include a first portion CP31, which conformally covers the upper surface L1A and the sidewall LIB of the mesa portion LM of the lower insulating film L31, and a second portion CP32 conformally covering inner surfaces of each of the plurality of trenches T3, the inner surfaces including the inner sidewall L1C of each of the plurality of trenches T3. In some embodiments, as shown in FIG. 5, a vertical level of a lowermost surface, which is closest to the lower interlayer dielectric UDL, of the second portion CP32 of the capacitor CP3 may be farther from the lower interlayer dielectric UDL than a vertical level of a lowermost surface, which is closest to the lower interlayer dielectric UDL, of the first portion CP31 of the capacitor CP3. However, the inventive concept is not limited thereto. For example, unlike the example shown in FIG. 5, the vertical level of the lowermost surface of the second portion CP32 may be equal to or similar to the vertical level of the lowermost surface of the first portion CP31, or the vertical level of the lowermost surface of the second portion CP32 may be closer to the lower interlayer dielectric UDL than the vertical level of the lowermost surface of the first portion CP31.

A plurality of air gaps may be included in an upper insulating film L32 of the image sensor 300. The plurality of air gaps may include a plurality of first air gaps AG31, which each have sides facing the sidewall LIB of the mesa portion LM in the first horizontal direction (X direction) or the second horizontal direction (Y direction), and a plurality of second air gaps AG32, which each face the inner sidewall L1C of each of the plurality of trenches T3 in the second horizontal direction (Y direction). Each of the plurality of second air gaps AG32 may overlap the capacitor CP3 in the vertical direction (Z direction). Each of the plurality of second air gaps AG32 may be apart from the inner sidewall L1C of the trench T3 with the capacitor CP3 therebetween.

The size of each of the plurality of first air gaps AG31 and the plurality of second air gaps AG32 in the vertical direction (Z direction) may be defined by the upper insulating film L32. In the vertical direction (Z direction), the size of each of the plurality of second air gaps AG32 may be less than the size of each of the plurality of first air gaps AG31.

In the image sensor 300, a plurality of capacitors CP3 may each include portions through which the first via contact VC1 and the second via contact VC2 respectively pass. The lower insulating film L31 may include a flat portion, which is apart from the non-flat surface NPS3 of the lower insulating film L31 in the second horizontal direction (Y direction) and has a flat upper surface, and the first via contact VC1 and the second via contact VC2 may pass through the capacitor CP3 on the flat portion in the vertical direction (Z direction).

Each of the first via contact VC1 and the second via contact VC2 may pass through the upper insulating film L32, the capacitor CP3, and the lower insulating film L31 in the vertical direction (Z direction) and thus be connected between one of the plurality of lower wiring patterns ML and one of the plurality of upper wiring patterns MU. The first via contact VC1 and the second via contact VC2, which pass through one capacitor CP3, may be apart from each other in the second horizontal direction (Y direction). More detailed configurations of the first via contact VC1 and the second via contact VC2 are the same as described with reference to FIGS. 2, 3B, and 3C.

Because the image sensor 300 includes the capacitor CP3 conformally covering the non-flat surface NPS3 of the lower insulating film L31, the capacitor CP3 may have an increased effective area and thus have increased capacitance per unit area. In addition, in the image sensor 300, because the plurality of first air gaps AG31 and the plurality of second air gaps AG32 are arranged in the upper insulating film L32 around the capacitor CP3, unintended coupling capacitance between the capacitor CP3 and the plurality of upper wiring patterns MU may be reduced and the stress in the upper insulating film L32, which is arranged between the plurality of capacitors CP3 and the plurality of upper wiring patterns MU, may be alleviated, thereby preventing defects due to an unintended excess of stress. Therefore, the reliability of the image sensor 300 may improve.

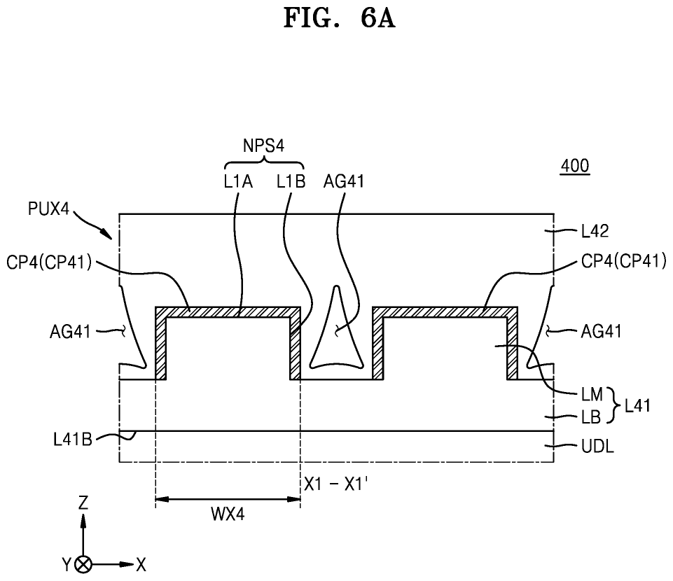

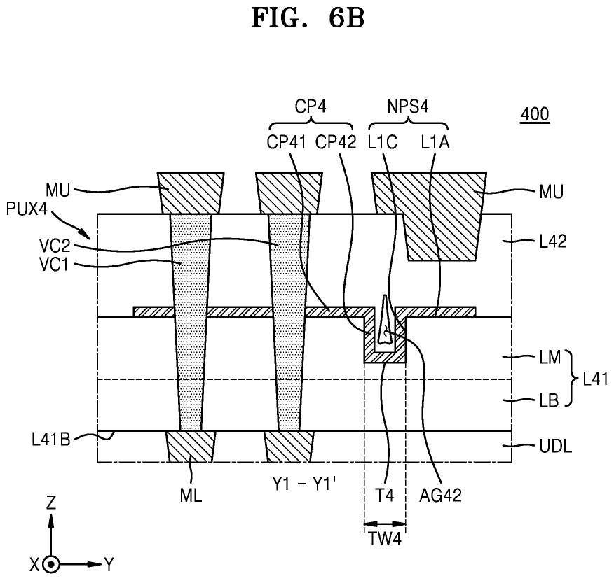

FIGS. 6A and 6B are cross-sectional views illustrating an image sensor 400 according to some embodiments, and in particular, FIG. 6A is a cross-sectional view of a portion of the image sensor 400, which corresponds to the cross-section taken along the line X1-X1′ of FIG. 2, and FIG. 6B is a cross-sectional view of a portion of the image sensor 400, which corresponds to the cross-section taken along the line Y1-Y1′ of FIG. 2. In FIGS. 6A and 6B, the same reference numerals as in FIGS. 2 and 3A to 3C respectively denote the same members, and here, repeated descriptions thereof are omitted.

Referring to FIGS. 6A and 6B, the image sensor 400 has mostly the same configuration as the image sensor 100 described with reference to FIGS. 2 and 3A to 3C. Similar to the description made with reference to FIG. 2, the image sensor 400 may include a plurality of unit pixels PXU4, which are repeatedly arranged in the first horizontal direction (X direction) and the second horizontal direction (Y direction) to form a matrix-formed arrangement and thus have a 2-dimensional array structure. The plurality of unit pixels PXU4 of the image sensor 400 may have mostly the same configuration as the plurality of unit pixels PXU described with reference to FIGS. 3A to 3C. However, the plurality of unit pixels PXU4 may respectively include a plurality of capacitors CP4.

The plurality of capacitors CP4 have mostly the same configuration as the plurality of capacitors CP1 described with reference to FIGS. 3A to 3C. However, each of the plurality of capacitors CP4 may be arranged on a lower insulating film L41. The lower insulating film L41 includes the base portion LB and the plurality of mesa portions LM, which are integrally connected to each other, and a trench T4 is formed in the upper surface of each of the plurality of mesa portions LM to be recessed toward a lower surface L41B of the lower insulating film L41.

The lower insulating film L41 may include the plurality of mesa portions LM in the first horizontal direction (X direction), and the plurality of mesa portions LM may extend lengthwise in the second horizontal direction (Y direction). A width TW4 of the trench T4 in the second horizontal direction (Y direction) may be less than a width WX4 of each of the plurality of capacitors CP4 in the first horizontal direction (X direction).

The mesa portion LM of the lower insulating film L41 may include a portion protruding in the vertical direction (Z direction) from the base portion LB. A non-flat surface NPS4 of the lower insulating film L41 may include the upper surface L1A of the mesa portion LM, the sidewall L1B of the mesa portion LM, and the inner sidewall L1C of the trench T4. Herein, the sidewall LIB of the mesa portion LM and the inner sidewall L1C of the trench T4 may each be referred to as a second surface.

Each of the plurality of capacitors CP4 may be in contact with the upper surface L1A and the sidewall LIB of the mesa portion LM and the inner sidewall L1C of the trench T4, which are included in the non-flat surface NPS4 of the lower insulating film L41. Each of the plurality of capacitors CP4 may conformally cover the non-flat surface NPS4 of the lower insulating film L41 along the contour of the non-flat surface NPS4 of the lower insulating film L41. Each of the plurality of capacitors CP4 may include a first portion CP41, which conformally covers the upper surface L1A and the sidewall LIB of the mesa portion LM of the lower insulating film L41, and a second portion CP42 conformally covering inner surfaces of the trench T4, which include the inner sidewall L1C of the trench T4.

In some embodiments, in each of the plurality of capacitors CP4, a vertical level of a lowermost surface, which is closest to the lower interlayer dielectric UDL, of the second portion CP42 may be farther from the lower interlayer dielectric UDL than a vertical level of a lowermost surface, which is closest to the lower interlayer dielectric UDL, of the first portion CP41. However, the inventive concept is not limited hereto.

A plurality of air gaps may be included in an upper insulating film L42 of the image sensor 400. The plurality of air gaps may include a plurality of first air gaps AG41, which each have sides facing the sidewall LIB of the mesa portion LM in the first horizontal direction (X direction), and a second air gap AG42 facing the inner sidewall L1C of the trench T4 in the second horizontal direction (Y direction). The second air gap AG42 may overlap a capacitor CP4 in the vertical direction (Z direction). The second air gap AG42 may be apart from the inner sidewall L1C of the trench T4 with the capacitor CP4 therebetween.

In the image sensor 400, one first air gap AG41 may be arranged between each two capacitors CP4 from among the plurality of capacitors CP4 in the first horizontal direction (X direction), and one second air gap AG42 may be arranged above each of the plurality of capacitors CP4 on the non-flat surface NPS4 of the lower insulating film L41. The first air gap AG41 may not be arranged between two capacitors CP4 adjacent to each other in the second horizontal direction (Y direction) from among the plurality of capacitors CP4.

The size of each of the plurality of first air gaps AG41 and the second air gap AG42 in the vertical direction (Z direction) may be defined by the upper insulating film L42. In the vertical direction (Z direction), the size of the second air gap AG42 may be less than the size of each of the plurality of first air gaps AG41.

In the image sensor 400, each of the plurality of capacitors CP4 may include portions through which the first via contact VC1 and the second via contact VC2 respectively pass. The lower insulating film L41 may include a flat portion, which is apart from the non-flat surface NPS4 of the lower insulating film L41 in the second horizontal direction (Y direction) and has a flat upper surface, and the first via contact VC1 and the second via contact VC2 may pass through the capacitor CP4 on the flat portion in the vertical direction (Z direction).

Each of the first via contact VC1 and the second via contact VC2 may pass through the upper insulating film L42, the capacitor CP4, and the lower insulating film L41 in the vertical direction (Z direction) and thus be connected between one of the plurality of lower wiring patterns ML and one of the plurality of upper wiring patterns MU. The first via contact VC1 and the second via contact VC2, which pass through one capacitor CP4, may be apart from each other in the second horizontal direction (Y direction). More detailed configurations of the first via contact VC1 and the second via contact VC2 are the same as described with reference to FIGS. 2, 3B, and 3C.

Because the image sensor 400 includes the plurality of capacitors CP4 conformally covering the non-flat surface NPS4 of the lower insulating film L41, each of the plurality of capacitors CP4 may have an increased effective area and thus have increased capacitance per unit area. In addition, in the image sensor 400, because the plurality of first air gaps AG41 and the second air gap AG42 are arranged in the upper insulating film L42 around each of the plurality of capacitors CP4, unintended coupling capacitance between the plurality of capacitors CP4 and the plurality of upper wiring patterns MU may be reduced and the stress in the upper insulating film L42, which is arranged between the plurality of capacitors CP4 and the plurality of upper wiring patterns MU, may be alleviated, thereby preventing defects due to an unintended excess of stress. Therefore, the reliability of the image sensor 400 may improve.

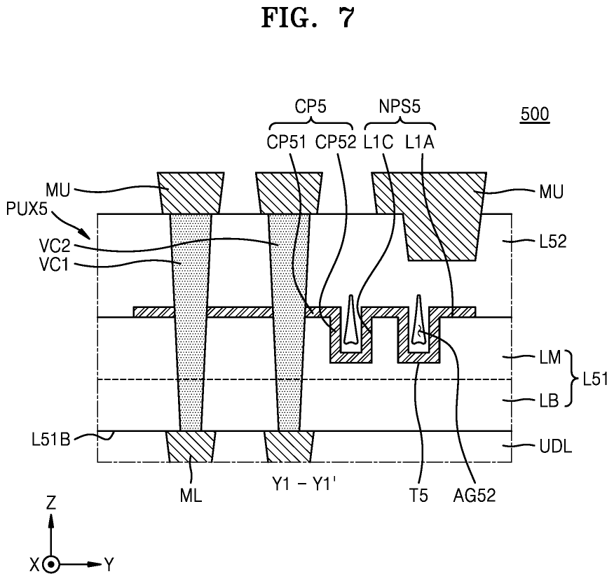

FIG. 7 is a cross-sectional view illustrating an image sensor 500 according to some embodiments. FIG. 7 illustrates a cross-sectional configuration of a portion of the image sensor 500, which corresponds to the cross-section taken along the line Y1-Y1′ of FIG. 2. A cross-sectional configuration of a portion of the image sensor 500, which corresponds to the cross-section taken along the line X1-X1′ of FIG. 2, may be the same as or similar to that described with reference to FIG. 6A. In FIG. 7, the same reference numerals as in FIGS. 2 to 6B respectively denote the same members, and here, repeated descriptions thereof are omitted.

Referring to FIG. 7, the image sensor 500 has mostly the same configuration as the image sensor 400 described with reference to FIGS. 6A and 6B. Similar to the description made with reference to FIG. 2, the image sensor 500 may include a plurality of unit pixels PXU5, which are repeatedly arranged in the first horizontal direction (X direction) and the second horizontal direction (Y direction) to form a matrix-formed arrangement and thus have a 2-dimensional array structure. A unit pixel PXU5 of the image sensor 500 may have mostly the same configuration as the unit pixel PXU2 described with reference to FIGS. 4A and 4B. However, the unit pixel PXU5 includes a capacitor CP5.

The capacitor CP5 may have mostly the same configuration as the capacitor CP4 described with reference to FIGS. 6A and 6B. However, the capacitor CP4 may be arranged on a lower insulating film L51. The lower insulating film L51 includes the base portion LB and the mesa portion LM, which are integrally connected to each other, and a plurality of trenches T5 are formed in the upper surface of the mesa portion LM to be recessed toward a lower surface L51B of the lower insulating film L51. In the second horizontal direction (Y direction), respective widths of the plurality of trenches T5 may be equal to each other or may be different from each other. In the second horizontal direction (Y direction), the width of each of the plurality of trenches T5 may be, but is not limited to, about 200 nm to about 500 nm, for example, about 300 nm to about 400 nm. A more detailed configuration of each of the plurality of trenches T5 may be the same as that of the trench T4 described with reference to FIGS. 6A and 6B.

The mesa portion LM of the lower insulating film L51 may include a portion protruding in the vertical direction (Z direction) from the base portion LB. A non-flat surface NPS5 of the lower insulating film L51 may include the upper surface L1A of the mesa portion LM, the sidewall LIB (see FIG. 6A) of the mesa portion LM, and the inner sidewall L1C of each of the plurality of trenches T5. Herein, the sidewall LIB (see FIG. 6A) of the mesa portion LM and the inner sidewall L1C of each of the plurality of trenches T5 may each be referred to as a second surface.

The capacitor CP5 may be in contact with the upper surface L1A and the sidewall LIB of the mesa portion LM and the inner sidewall L1C of each of the plurality of trenches T5, which are included in the non-flat surface NPS5 of the lower insulating film L51. The capacitor CP5 may conformally cover the non-flat surface NPS5 of the lower insulating film L51 along the contour of the non-flat surface NPS5 of the lower insulating film L51. The capacitor CP5 may include a first portion CP51, which conformally covers the upper surface L1A and the sidewall LIB of the mesa portion LM of the lower insulating film L51, and a second portion CP52 conformally covering inner surfaces of each of the plurality of trenches T5, the inner surfaces including the inner sidewall L1C of each of the plurality of trenches T5. In some embodiments, as shown in FIG. 7, a vertical level of a lowermost surface, which is closest to the lower interlayer dielectric UDL, of the second portion CP52 of the capacitor CP5 may be farther from the lower interlayer dielectric UDL than a vertical level of a lowermost surface, which is closest to the lower interlayer dielectric UDL, of the first portion CP51 of the capacitor CP5.

A plurality of air gaps may be included in an upper insulating film L52 of the image sensor 500. The plurality of air gaps may include the plurality of first air gaps AG41, which each have sides that face the sidewall LIB of the mesa portion LM in the first horizontal direction (X direction), similar to the example shown in FIG. 6A, and a plurality of second air gaps AG52, which each have sides that face the inner sidewall L1C of each of the plurality of trenches T5 in the second horizontal direction (Y direction), as shown in FIG. 7. Each of the plurality of second air gaps AG52 may overlap the capacitor CP5 in the vertical direction (Z direction). Each of the plurality of second air gaps AG52 may be apart from the inner sidewall L1C of the trench T5 with the capacitor CP5 therebetween. The size of each of the plurality of second air gaps AG52 in the vertical direction (Z direction) may be defined by the upper insulating film L52.

In the image sensor 500, a plurality of capacitors CP5 may each include portions through which the first via contact VC1 and the second via contact VC2 respectively pass. The lower insulating film L51 may include a flat portion, which is apart from the non-flat surface NPS5 of the lower insulating film L51 in the second horizontal direction (Y direction) and has a flat upper surface, and the first via contact VC1 and the second via contact VC2 may pass through the capacitor CP5 on the flat portion in the vertical direction (Z direction).

Each of the first via contact VC1 and the second via contact VC2 may pass through the upper insulating film L52, the capacitor CP5, and the lower insulating film L51 in the vertical direction (Z direction) and thus be connected between one of the plurality of lower wiring patterns ML and one of the plurality of upper wiring patterns MU. The first via contact VC1 and the second via contact VC2, which pass through one capacitor CP5, may be apart from each other in the second horizontal direction (Y direction). More detailed configurations of the first via contact VC1 and the second via contact VC2 are the same as described with reference to FIGS. 2, 3B, and 3C.

Because the image sensor 500 includes the capacitor CP5 conformally covering the non-flat surface NPS5 of the lower insulating film L51, the capacitor CP5 may have an increased effective area and thus have increased capacitance per unit area. In addition, in the image sensor 500, because the plurality of first air gaps AG41 (see FIG. 6A) and the plurality of second air gaps AG52 are arranged in the upper insulating film L52 around the capacitor CP5, unintended coupling capacitance between the capacitor CP5 and the plurality of upper wiring patterns MU may be reduced and the stress in the upper insulating film L52, which is arranged between the plurality of capacitors CP5 and the plurality of upper wiring patterns MU, may be alleviated, thereby preventing defects due to an unintended excess of stress. Therefore, the reliability of the image sensor 500 may improve.

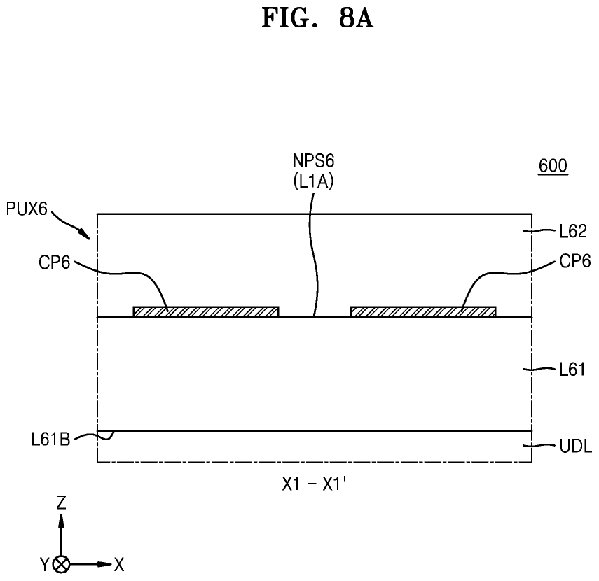

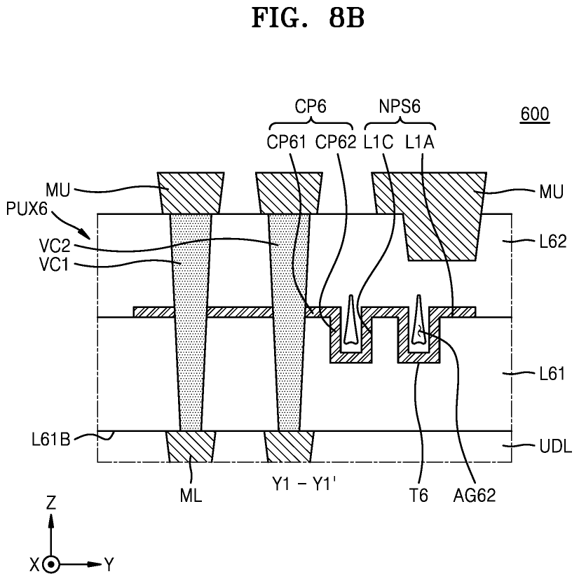

FIGS. 8A and 8B are cross-sectional views illustrating an image sensor 600 according to some embodiments, and in particular, FIG. 8A is a cross-sectional view of a portion of the image sensor 600, which corresponds to the cross-section taken along the line X1-X1′ of FIG. 2, and FIG. 8B is a cross-sectional view of a portion of the image sensor 600, which corresponds to the cross-section taken along the line Y1-Y1′ of FIG. 2. In FIGS. 8A and 8B, the same reference numerals as in FIGS. 2 and 3A to 3C respectively denote the same members, and here, repeated descriptions thereof are omitted.

Referring to FIGS. 8A and 8B, the image sensor 600 has mostly the same configuration as the image sensor 100 described with reference to FIGS. 2 and 3A to 3C. Similar to the description made with reference to FIG. 2, the image sensor 600 may include a plurality of unit pixels PXU6, which are repeatedly arranged in the first horizontal direction (X direction) and the second horizontal direction (Y direction) to form a matrix-formed arrangement and thus have a 2-dimensional array structure. The plurality of unit pixels PXU6 of the image sensor 600 may have mostly the same configuration as the plurality of unit pixels PXU described with reference to FIGS. 3A to 3C. However, the plurality of unit pixels PXU6 may respectively include a plurality of capacitors CP6.

The plurality of capacitors CP6 have mostly the same configuration as the plurality of capacitors CP1 described with reference to FIGS. 3A to 3C. However, each of the plurality of capacitors CP6 may be arranged on a lower insulating film L61. A plurality of trenches T6 are formed in an upper surface of the lower insulating film L61 to be recessed toward a lower surface L61B of the lower insulating film L61.

The lower insulating film L61 may include a non-flat surface NPS6, which includes the upper surface of the lower insulating film L61 and inner surfaces of each of the plurality of trenches T6, the inner surfaces including the inner sidewall L1C of each of the plurality of trenches T6. Herein, the upper surface of the lower insulating film L61 may be referred to as a first surface, and the inner sidewall L1C of each of the plurality of trenches T6 may be referred to as a second surface.

Each of the plurality of capacitors CP6 may be in contact with the upper surface of the lower insulating film L61 and the inner surfaces of each of the plurality of trenches T6, which are included in the non-flat surface NPS6 of the lower insulating film L61, the inner surfaces including the inner sidewall L1C of each of the plurality of trenches T6. Each of the plurality of capacitors CP6 may conformally cover the non-flat surface NPS6 of the lower insulating film L61 along the contour of the non-flat surface NPS6 of the lower insulating film L61. Each of the plurality of capacitors CP6 may include a first portion CP61, which conformally covers the upper surface of the lower insulating film L61, and a second portion CP62 conformally covering the inner surfaces of each of the plurality of trenches T6, the inner surfaces including the inner sidewall L1C of each of the plurality of trenches T6.

A plurality of air gaps may be included in an upper insulating film L62 of the image sensor 600. The plurality of air gaps may include a plurality of air gaps AG62 each having sides facing the inner sidewall L1C of each of the plurality of trenches T6 in the second horizontal direction (Y direction). Each of the plurality of air gaps AG62 may overlap a capacitor CP6 in the vertical direction (Z direction). Each of the plurality of air gaps AG62 may be apart from the inner sidewall L1C of a trench T6 with the capacitor CP6 therebetween. The size of each of the plurality of air gaps AG62 in the vertical direction (Z direction) may be defined by the upper insulating film L62.

In the image sensor 600, the plurality of air gaps AG62 may be arranged above each of the plurality of capacitors CP6 on the non-flat surface NPS6 of the lower insulating film L61, and no air gap may be arranged between two capacitors CP6 adjacent to each other in each of the first horizontal direction (X direction) and the second horizontal direction (Y direction) from among the plurality of capacitors CP6.

In the image sensor 600, each of the plurality of capacitors CP6 may include portions through which the first via contact VC1 and the second via contact VC2 respectively pass. The lower insulating film L61 may include a flat portion, which is apart from the non-flat surface NPS6 of the lower insulating film L61 in the second horizontal direction (Y direction) and has a flat upper surface, and the first via contact VC1 and the second via contact VC2 may pass through the capacitor CP6 on the flat portion in the vertical direction (Z direction).

Each of the first via contact VC1 and the second via contact VC2 may pass through the upper insulating film L62, the capacitor CP6, and the lower insulating film L61 in the vertical direction (Z direction) and thus be connected between one of the plurality of lower wiring patterns ML and one of the plurality of upper wiring patterns MU. The first via contact VC1 and the second via contact VC2, which pass through one capacitor CP6, may be apart from each other in the second horizontal direction (Y direction). More detailed configurations of the first via contact VC1 and the second via contact VC2 are the same as described with reference to FIGS. 2, 3B, and 3C.

Because the image sensor 600 includes the plurality of capacitors CP6 conformally covering the non-flat surface NPS6 of the lower insulating film L61, each of the plurality of capacitors CP6 may have an increased effective area and thus have increased capacitance per unit area. In addition, because the image sensor 600 includes the plurality of air gaps AG62 arranged in the upper insulating film L62 around each of the plurality of capacitors CP6, unintended coupling capacitance between the plurality of capacitors CP6 and the plurality of upper wiring patterns MU may be reduced and the stress in the upper insulating film L62, which is arranged between the plurality of capacitors CP6 and the plurality of upper wiring patterns MU, may be alleviated, thereby preventing defects due to an unintended excess of stress. Therefore, the reliability of the image sensor 600 may improve.

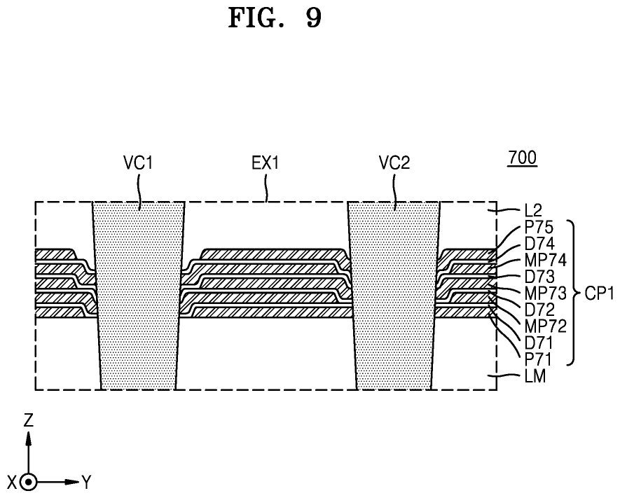

FIG. 9 is a cross-sectional view illustrating an image sensor 700 according to some embodiments. FIG. 9 is an enlarged cross-sectional view of another example configuration of the region EX of FIG. 3B. In FIG. 9, the same reference numerals as in FIGS. 2 and 3A to 3C respectively denote the same members, and here, repeated descriptions thereof are omitted.

Referring to FIG. 9, the image sensor 700 may have mostly the same configuration as the image sensor 100 described with reference to FIGS. 2 and 3A to 3C. The capacitor CP1 of the image sensor 700 may include an MIM capacitor, which includes a plurality of electrode plates sequentially stacked on the mesa portion LM of the lower insulating film L1. However, in the image sensor 700, the plurality of electrode plates may include a lower electrode plate P71, an upper electrode plate P75, and a plurality of intermediate electrode plates. The plurality of intermediate electrode plates may be arranged between the lower electrode plate P71 and the upper electrode plate P75. The plurality of intermediate electrode plates may include a first intermediate electrode plate MP72, a second intermediate electrode plate MP73, and a third intermediate electrode plate MP74, which are stacked in the stated order from the lower electrode plate P71 toward the upper electrode plate P75.

In addition, the capacitor CP1 may include a plurality of dielectric films D71, D72, D73, and D74 respectively arranged between electrode plates adjacent to each other from among the lower electrode plate P71, the upper electrode plate P75, the first intermediate electrode plate MP72, the second intermediate electrode plate MP73, and the third intermediate electrode plate MP74, such that the lower electrode plate P71, the upper electrode plate P75, the first intermediate electrode plate MP72, the second intermediate electrode plate MP73, and the third intermediate electrode plate MP74 are apart from each other.

The first via contact VC1 may be in contact with the lower electrode plate P71, the second intermediate electrode plate MP73, and the upper electrode plate P75 and may be apart from (e.g., physically spaced apart from and electrically insulated from) the first intermediate electrode plate MP72 and the third intermediate electrode plate MP74. The second via contact VC2 may be in contact with the first intermediate electrode plate MP72 and the third intermediate electrode plate MP74 and may be apart from (e.g., physically spaced apart from and electrically insulated from) the lower electrode plate P71, the second intermediate electrode plate MP73, and the upper electrode plate P75.

In some embodiments, each of the lower electrode plate P71, the upper electrode plate P75, the first intermediate electrode plate MP72, the second intermediate electrode plate MP73, and the third intermediate electrode plate MP74 may include or be a metal, a conductive metal nitride, or a combination thereof. For example, each of the lower electrode plate P71, the upper electrode plate P75, the first intermediate electrode plate MP72, the second intermediate electrode plate MP73, and the third intermediate electrode plate MP74 may include or be, but is not limited to, TiN. In some embodiments, each of the lower electrode plate P71, the upper electrode plate P75, the first intermediate electrode plate MP72, the second intermediate electrode plate MP73, and the third intermediate electrode plate MP74 may have, but is not limited to, a thickness of about 10 nm to about 100 nm, for example, about 30 nm to about 50 nm. Respective detailed configurations of the plurality of dielectric films D71, D72, D73, and D74 are substantially the same as those of the plurality of dielectric films D1 and D2 described with reference to FIG. 3C.

FIG. 9 illustrates, as an example, the MIM capacitor in which three intermediate electrode plates apart from each other, that is, the first to third intermediate electrode plates MP72, MP73, and MP74, are arranged between the lower electrode plate P71 and the upper electrode plate P75, but the inventive concept is not limited thereto. For example, at least two intermediate electrode plates apart from each other may be arranged between the lower electrode plate P71 and the upper electrode plate P75, and the number of intermediate electrode plates arranged between the lower electrode plate P71 and the upper electrode plate P75 is not particularly limited.

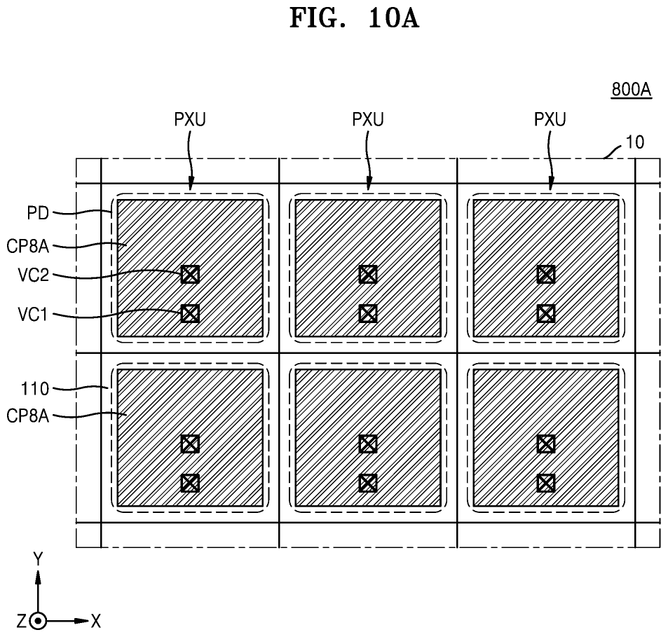

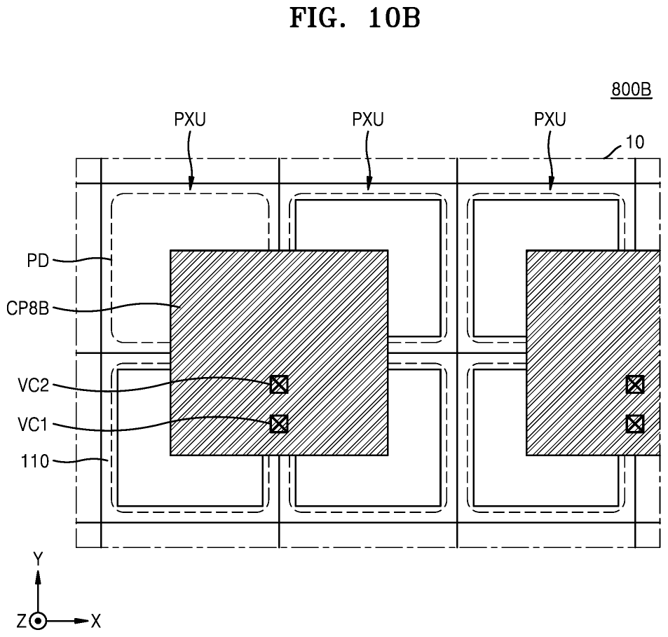

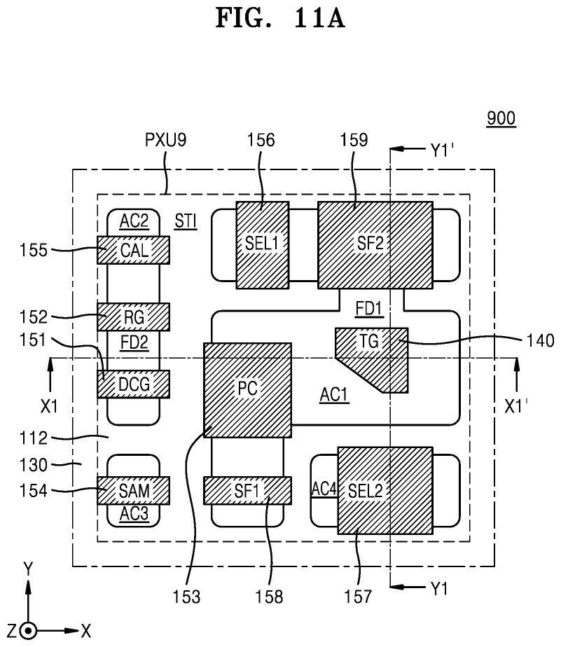

FIG. 10A is a planar layout diagram illustrating some components of the pixel array 10, which is included in an image sensor 800A according to some embodiments. In FIG. 10A, the same reference numerals as in FIG. 2 respectively denote the same members, and here, repeated descriptions thereof are omitted.

Referring to FIG. 10A, the pixel array 10 of the image sensor 800A may include the plurality of unit pixels PXU. The plurality of unit pixels PXU may respectively include the plurality of photodiodes PD, which are arranged in the substrate 110, and a plurality of capacitors CP8A, which are arranged over the substrate 110 and respectively overlap the plurality of photodiodes PD in the vertical direction (Z direction). The plurality of capacitors CP8A may be arranged at regular pitches in the first horizontal direction (X direction) and the second horizontal direction (Y direction) over the substrate 110. Each of the plurality of capacitors CP8A may overlap one photodiode PD selected from the plurality of photodiodes PD in the vertical direction (Z direction). One capacitor CP8A may be arranged over one photodiode PD.

FIG. 10B is a planar layout diagram illustrating some components of the pixel array 10, which is included in an image sensor 800B according to some embodiments. In FIG. 10B, the same reference numerals as in FIG. 2 respectively denote the same members, and here, repeated descriptions thereof are omitted.

Referring to FIG. 10B, the pixel array 10 of the image sensor 800B may include the plurality of unit pixels PXU. The plurality of unit pixels PXU may respectively include the plurality of photodiodes PD, which are arranged in the substrate 110, and a plurality of capacitors CP8B, which are arranged over the substrate 110 and respectively overlap the plurality of photodiodes PD in the vertical direction (Z direction). The plurality of capacitors CP8B may be arranged at regular pitches in the first horizontal direction (X direction) and the second horizontal direction (Y direction) over the substrate 110. Each of the plurality of capacitors CP8B may overlap four photodiodes PD selected from the plurality of photodiodes PD in the vertical direction (Z direction). Four unit pixels PXU adjacent to each other may share one capacitor CP8A.

FIG. 10B illustrates a configuration in which four unit pixels PXU share one capacitor CP8A, but the inventive concept is not limited thereto. For example, N unit pixels PXU (where N is a natural number of 2 or more) may share one capacitor CP8A.

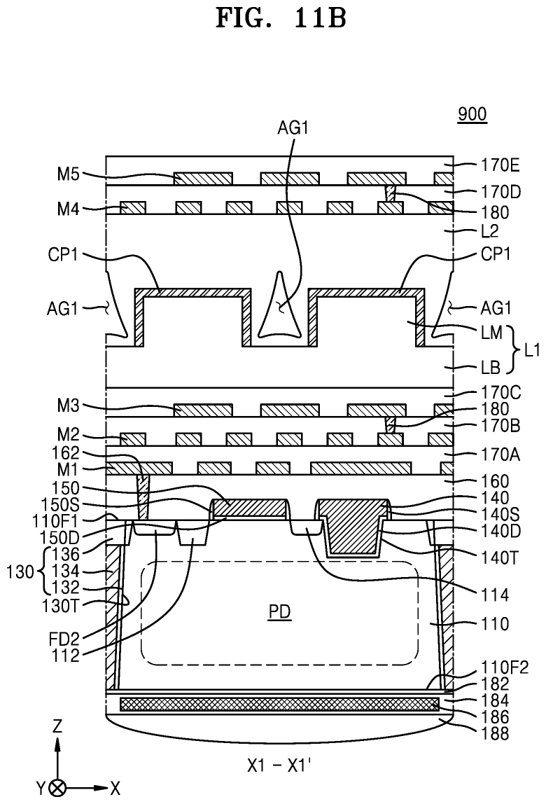

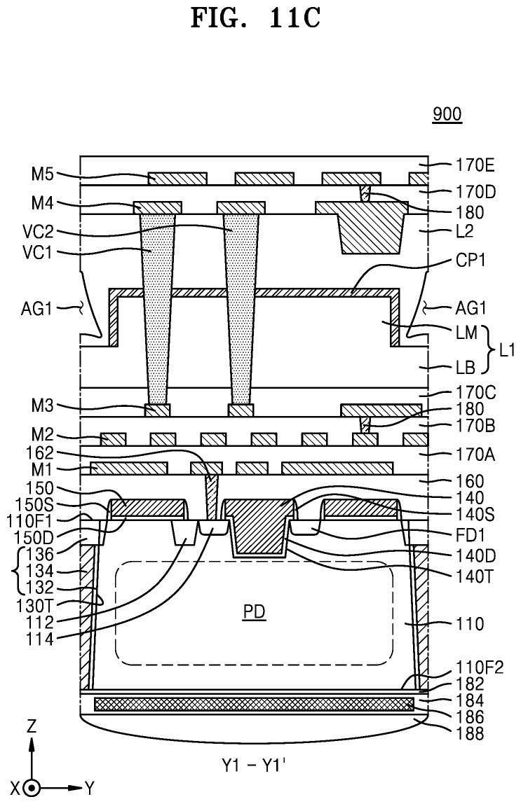

FIG. 11A is a layout diagram of an image sensor 900 according to some embodiments, FIG. 11B is a cross-sectional view of the image sensor 900, taken along the line X1-X1′ of FIG. 11A, and FIG. 11C is a cross-sectional view of the image sensor 900, taken along the line Y1-Y1′ of FIG. 11A. In FIGS. 11A to 11C, the same reference numerals as in FIGS. 2 and 3A to 3C respectively denote the same members, and here, repeated descriptions thereof are omitted.

Referring to FIGS. 11A to 11C, the image sensor 900 may include a global shutter-type image sensor. A unit pixel PXU9 of the image sensor 900 may include a photodiode PD, a transfer transistor TG, a first floating diffusion region FD1, a reset transistor RG, a dual conversion gain transistor DCG, a second floating diffusion region FD2, a first source follower transistor SF1, a pre-charge transistor PC, a sample transistor SAM, a calibration transistor CAL, a second source follower transistor SF2, a first select transistor SEL1, a second select transistor SEL2, and a plurality of capacitors CP1.

One unit pixel PXU9 may be electrically insulated from another unit pixel PXU9 adjacent thereto by a pixel device isolation film 130, and first to fourth active regions AC1, AC2, AC3, and AC4 may be defined in one unit pixel PXU9 by a device isolation film 112. A plurality of ion-implanted regions 114 may be arranged in the first to fourth active regions AC1, AC2, AC3, and AC4.

The photodiode PD, the transfer transistor TG, the first floating diffusion region FD1, the first source follower transistor SF1, the pre-charge transistor PC, the second source follower transistor SF2, and the first select transistor SEL1 may be arranged on the first active region AC1. The reset transistor RG, the dual conversion gain transistor DCG, the second floating diffusion region FD2, and the calibration transistor CAL may be arranged on the second active region AC2. The sample transistor SAM may be arranged on the third active region AC3, and the second select transistor SEL2 may be arranged on the fourth active region AC4.

The photodiode PD may include an N-type impurity region. The first floating diffusion region FD1 may be arranged in the first active region AC1 to be adjacent to the photodiode PD. A transfer gate electrode 140 of the transfer transistor TG may be arranged adjacent to the first floating diffusion region FD1.

A dual conversion gain gate electrode 151 of the dual conversion gain transistor DCG and a reset gate electrode 152 of the reset transistor RG may be arranged on the second active region AC2. The second floating diffusion region FD2 may be arranged in the second active region AC2 between the dual conversion gain gate electrode 151 and the reset gate electrode 152. The reset transistor RG and the dual conversion gain transistor DCG may share the second floating diffusion region FD2. The second floating diffusion region FD2 may function as a source or a drain of each of the reset transistor RG and the dual conversion gain transistor DCG.

In some embodiments, the dual conversion gain transistor DCG may be connected between the first floating diffusion region FD1 and the reset transistor RG. The reset transistor RG may be connected to the first floating diffusion region FD1 via the dual conversion gain transistor DCG. The reset transistor RG and the dual conversion gain transistor DCG may be connected in series to the first source follower transistor SF1.

The pre-charge transistor PC may be connected to the first source follower transistor SF1. A pre-charge gate electrode 153 of the pre-charge transistor PC may be arranged on the first active region AC1. The sample transistor SAM may be connected between the first source follower transistor SF1 and the pre-charge transistor PC. A sample gate electrode 154 of the sample transistor SAM may be arranged on the third active region AC3. The calibration transistor CAL may be connected to one capacitor CP1 selected from the plurality of capacitors CP1. A calibration gate electrode 155 of the calibration transistor CAL may be arranged on the second active region AC2. In some embodiments, unlike the example shown in FIG. 11A, the second select transistor SEL2 may be omitted.

As shown in FIGS. 11A and 11B, the substrate 110 may include a first surface 110F1 and a second surface 110F2, which are opposite to each other. Herein, the first surface 110F1 of the substrate 110 may be referred to as a frontside surface, and the second surface 110F2 of the substrate 110 may be referred to as a backside surface. In some embodiments, the substrate 110 may include a P-type semiconductor substrate. A plurality of unit pixels PXU9 may be arranged in a matrix form in the substrate 110.

The pixel device isolation film 130 may be arranged in the substrate 110, and the plurality of unit pixels PXU9 may be defined by the pixel device isolation film 130. The pixel device isolation film 130 may be arranged between one photodiode PD and another photodiode PD adjacent thereto from among the plurality of photodiodes PD. One photodiode PD and another photodiode PD adjacent thereto may be isolated from each other by the pixel device isolation film 130.

The pixel device isolation film 130 may be formed in a pixel trench 130T, which passes through the substrate 110 in the vertical direction (Z direction). The pixel device isolation film 130 may include an insulating film 132 and a conductive film 134 surrounded by the insulating film 132, the conductive film 134 filling a space defined by the insulating film 132 in the pixel trench 130T. In some embodiments, the insulating film 132 may include or be a metal oxide, such as hafnium oxide, aluminum oxide, or tantalum oxide. In some embodiments, the insulating film 132 may include or be an insulating material, such as silicon oxide, silicon nitride, or silicon oxynitride. The conductive film 134 may include or be at least one of doped polysilicon, a metal, a metal silicide, a metal nitride, and a metal-containing film. A portion of the pixel trench 130T, which is adjacent to the first surface 110F1 of the substrate 110, may be filled with an upper insulating film 136. In some embodiments, the upper insulating film 136 may be in contact with an end of each of the insulating film 132 and the conductive film 134.

As shown in FIGS. 11B and 11C, the device isolation film 112, which defines the first to fourth active regions ACT1, ACT2, ACT3, and ACT4, may be arranged adjacent to the first surface 110F1 of the substrate 110. The device isolation film 112 may include a portion surrounding a portion of the pixel device isolation film 130.

Transistors constituting a pixel circuit (not shown) may be arranged on the first to fourth active regions ACT1, ACT2, ACT3, and ACT4. As shown in FIG. 11A, the transfer gate electrode 140, the dual conversion gain gate electrode 151, the reset gate electrode 152, the pre-charge gate electrode 153, the sample gate electrode 154, the calibration gate electrode 155, first and second select gate electrodes 156 and 157, and first and second source follower gate electrodes 158 and 159 may be arranged on the first surface 110F1 of the substrate 110.

As shown in FIGS. 11B and 11C, the transfer gate electrode 140 may be arranged in a transfer gate trench 140T, which extends from the first surface 110F1 of the substrate 110 to the inside of the substrate 110. Each of the dual conversion gain gate electrode 151, the reset gate electrode 152, the pre-charge gate electrode 153, the sample gate electrode 154, the calibration gate electrode 155, the first and second select gate electrodes 156 and 157, and the first and second source follower gate electrodes 158 and 159 may be shown as one of a plurality of gate electrodes 150 in FIGS. 11B and 11C, and the gate electrode 150 may be arranged on the first surface 110F1 of the substrate 110. In some embodiments, each of the transfer gate electrode 140 and the plurality of gate electrodes 150 may include or be formed of at least one of doped polysilicon, a metal, a metal silicide, a metal nitride, and a metal-containing film.

A transfer gate dielectric film 140D may be arranged on an inner surface of the transfer gate trench 140T to surround a sidewall and a lower surface of the transfer gate electrode 140. An insulating spacer 140S may be arranged on the sidewall of the transfer gate electrode 140. A gate dielectric film 150D may be arranged between the gate electrode 150 and the first surface 110F1 of the substrate 110. An insulating spacer 150S may be arranged on a sidewall of the gate electrode 150.

An interlayer dielectric 160 may be arranged on the first surface 110F1 of the substrate 110 to cover the transfer gate electrode 140 and the plurality of gate electrodes 150. A wiring structure, which includes a plurality of interlayer dielectrics 170A, 170B, 170C, 170D, and 170E, a plurality of wiring patterns M1, M2, M3, M4, and M5, and a plurality of contact plugs 180, may be arranged on the interlayer dielectric 160.

An electrical signal converted by the photodiode PD may undergo signal processing by a plurality of transistors and the wiring structure, which are arranged on the first surface 110F1 of the substrate 110. The wiring structure may be selectively connected to the plurality of transistors via at least one contact plug 162 from among a plurality of contact plugs 162. The plurality of transistors may include the transfer transistor TG, the reset transistor RG, the dual conversion gain transistor DCG, the first source follower transistor SF1, the pre-charge transistor PC, the sample transistor SAM, the calibration transistor CAL, the second source follower transistor SF2, the first select transistor SEL 1, and the second select transistor SEL2, which are shown in FIG. 11A.

Each of the plurality of contact plugs 162, the plurality of wiring patterns M1, M2, M3, M4, and M5, and the plurality of contact plugs 180 may include or be formed of a metal, a conductive metal nitride, or a combination thereof. For example, each of the plurality of contact plugs 162, the plurality of wiring patterns M1, M2, M3, M4, and M5, and the plurality of contact plugs 180 may include or be, but is not limited to, Cu, Al, W, Ti, Mo, Ta, TiN, TaN, ZrN, WN, or a combination thereof. A plurality of interlayer dielectrics 160, 170A, 170B, 170C, 170D, and 170E may each include or be formed of an oxide film, a nitride film, or a combination thereof.

The plurality of interlayer dielectrics 160, 170A, 170B, 170C, 170D, and 170E, the plurality of contact plugs 162, the plurality of wiring patterns M1, M2, M3, M4, and M5, and the plurality of contact plugs 180 are not limited to the example shown in FIGS. 11B and 11C in terms of the number of layers and the arrangement of each thereof, and various modifications and changes may be made thereto, as needed.

In some embodiments, as shown in FIGS. 11B and 11C, the plurality of capacitors CP1 may be arranged between a plurality of wiring patterns M3 and a plurality of wiring patterns M4. The plurality of wiring patterns M3 and the interlayer dielectric 170C may be covered by the lower insulating film L1, and the plurality of capacitors CP1 may be arranged on the lower insulating film L1. The lower insulating film L1 may include the base portion LB and the plurality of mesa portions LM, which are integrally connected to each other. The upper surface L1A and the sidewall LIB of each of the plurality of mesa portions LM may provide the non-flat surface NPS (see FIGS. 3A and 3B) of a concave-convex shape onto the lower insulating film L1. Each of the plurality of capacitors CP1 may conformally cover the non-flat surface NPS of the lower insulating film L1 along the contour of the non-flat surface NPS of the lower insulating film L1. The plurality of capacitors CP1 may have a configuration selected from among the configuration described with reference to FIG. 3C, the configuration described with reference to FIG. 9, and various configurations modified and changed therefrom.

The plurality of capacitors CP1 and the lower insulating film L1 may be covered by the upper insulating film L2. The plurality of air gaps AG1 may be included in the upper insulating film L2. Each of the plurality of air gaps AG1 may have sides that face the sidewall LIB of the mesa portion LM in the first horizontal direction (X direction) or the second horizontal direction (Y direction). One air gap AG1 may be arranged between each two capacitors CP1 from among the plurality of capacitors CP1 in the first horizontal direction (X direction) and the second horizontal direction (Y direction). The upper insulating film L2 may be covered by a plurality of wiring patterns M4 and the interlayer dielectric 170D.

As shown in FIG. 11C, each of the first via contact VC1 and the second via contact VC2 may pass through the capacitor CP1 in the vertical direction (Z direction). Each of the plurality of capacitors CP1 may include a flat portion extending flat along the upper surface of the mesa portion LM, and the first via contact VC1 and the second via contact VC2 may pass through the flat portion in the vertical direction (Z direction). Each of the first via contact VC1 and the second via contact VC2 may pass through the upper insulating film L2, the capacitor CP1, and the lower insulating film L1 in the vertical direction (Z direction) and thus be connected between one of the plurality of wiring patterns M3 and one of the plurality of wiring patterns M4.

A more detailed configuration of each of the lower insulating film L1, the upper insulating film L2, the plurality of capacitors CP1, the first via contact VC1, and the second via contact VC2 is the same as described with reference to FIGS. 2, 3A, and 3B. Although a configuration, in which the plurality of capacitors CP1 are arranged between the plurality of wiring patterns M3 and the plurality of wiring patterns M4, is described in the present example, the inventive concept is not limited thereto. For example, the plurality of capacitors CP1 may be arranged between a plurality of wiring patterns M1 and a plurality of wiring patterns M2, between the plurality of wiring patterns M2 and the plurality of wiring patterns M3, or between the plurality of wiring patterns M4 and the plurality of wiring patterns M5, or over the plurality of wiring patterns M5.

Although it is described in the present example that the unit pixel PXU9 includes the capacitor CP1 described with reference to FIGS. 2, 3A, and 3B, the inventive concept is not limited thereto. For example, the unit pixel PXU9 may include, instead of the capacitor CP1, at least one capacitor selected from among the capacitors CP2, CP3, CP4, CP5, and CP6 shown in FIGS. 4A to 8B, the capacitors CP8A and CP8B shown in FIGS. 10A and 10B, and capacitors variously modified and changed therefrom without departing from the spirit and scope of the inventive concept.

As shown in FIGS. 11B and 11C, a backside insulating layer 182 may be arranged on the second surface 110F of the substrate 110. The backside insulating layer 182 may be in contact with the pixel device isolation film 130. In some embodiments, the backside insulating layer 182 may include or be a metal oxide, such as hafnium oxide, aluminum oxide, or tantalum oxide. In some embodiments, the backside insulating layer 182 may include or be an insulating material, such as silicon oxide, silicon nitride, silicon oxynitride, or a low-K material. A passivation layer 184, a color filter 186, and a micro-lens 188 may be arranged on or over the backside insulating layer 182. The color filter 186 and the micro-lens 188 may perform filtering and concentration on light incident from outside the image sensor 90 and cause the light to be incident on the photodiode PD. The micro-lens 188 may have an outwardly convex shape to concentrate light to be incident on the photodiode PD. The unit pixel PXU9 may have a backside illumination (BSI) structure, in which light is received from the second surface 110F2 of the substrate 102.

Because the image sensor 900 described with reference to FIGS. 11A to 11C includes the plurality of capacitors CP1 conformally covering the non-flat surface of the lower insulating film L1, each of the plurality of capacitors CP1 may have an increased effective area and thus have increased capacitance per unit area. In addition, in the image sensor 900, because the plurality of air gaps AG1 are arranged in the upper insulating film L2 around each of the plurality of capacitors CP1, unintended coupling capacitance between the plurality of capacitors CP1 and the plurality of wiring patterns M4 may be reduced and the stress in the upper insulating film L2, which is arranged between the plurality of capacitors CP1 and the plurality of wiring patterns M4, may be alleviated, thereby preventing defects due to an unintended excess of stress. Therefore, the reliability of the image sensor 900 may improve.

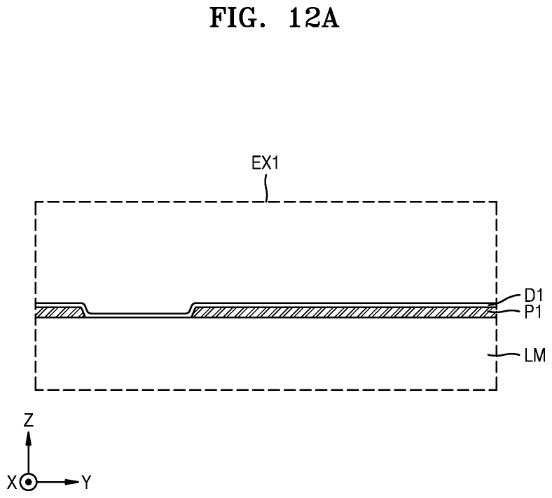

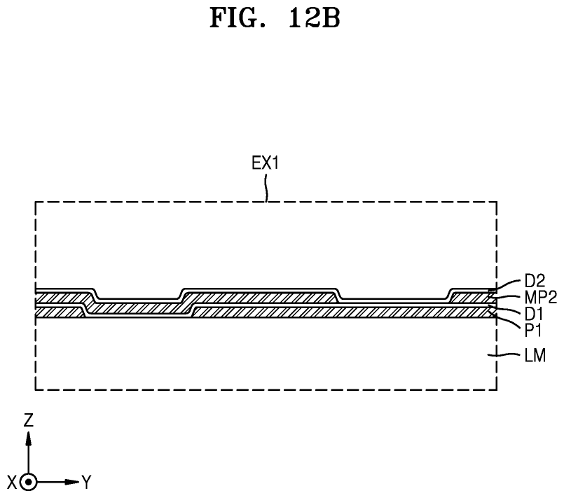

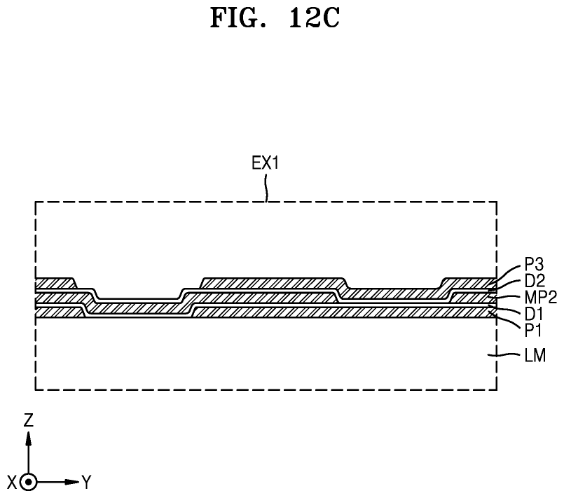

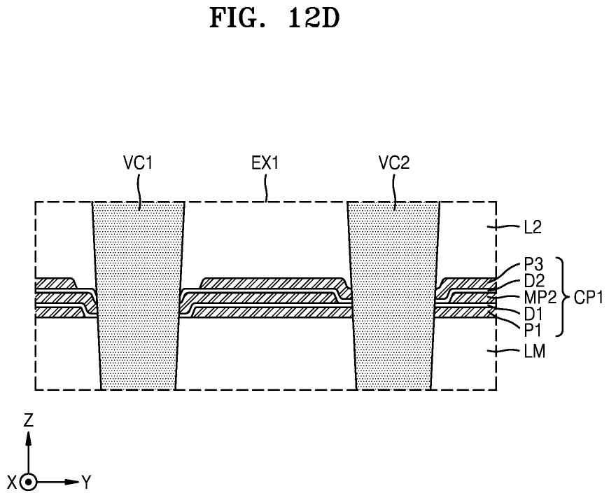

FIGS. 12A to 12D are cross-sectional views respectively illustrating a sequence of processes of an example method of fabricating the capacitor CP1 having the structure described with reference to FIG. 3C. In FIGS. 12A to 12D, the same reference numerals as in FIGS. 2 and 3A to 3C respectively denote the same members, and here, repeated descriptions thereof are omitted.

Referring to FIG. 12A, a first conductive layer may be formed on the lower insulating film L1 (see FIGS. 3A and 3B) including the mesa portion LM, followed by forming a first mask pattern (not shown) to partially cover the first conductive layer, and then, a portion of the first conductive layer may be removed by using the first mask pattern as an etch mask, thereby forming a plurality of lower electrode plates P1. Next, the first mask pattern may be removed, and a dielectric film D1 may be formed to cover the plurality of lower electrode plates P1.

The first conductive layer may include or be a metal, a conductive metal nitride, or a combination thereof. For example, the first conductive layer may include or be, but is not limited to, TiN. To form the first conductive layer, a sputtering process may be used. To form the dielectric film D1, an atomic layer deposition (ALD) process may be used.

Referring to FIG. 12B, a second conductive layer may be formed on the resulting product of FIG. 12A, followed by forming a second mask pattern (not shown) to partially cover the second conductive layer, and then, a portion of the second conductive layer may be removed by using the second mask pattern as an etch mask, thereby forming a plurality of intermediate electrode plates MP2. Next, the second mask pattern may be removed, and a dielectric film D2 may be formed to cover the plurality of intermediate electrode plates MP2. The plurality of intermediate electrode plates MP2 and the dielectric film D2 may each be formed to cover the mesa portion LM in a space between the plurality of lower electrode plates P1. Detailed configurations and formation methods of the second conductive layer and the dielectric film D2 are substantially the same as described regarding the first conductive layer and the dielectric film D1 with reference to FIG. 12A, respectively.

Referring to FIG. 12C, a third conductive layer may be formed on the resulting product of FIG. 12B, followed by forming a third mask pattern (not shown) to partially cover the third conductive layer, and then, a portion of the third conductive layer may be removed by using the third mask pattern as an etch mask, thereby forming a plurality of upper electrode plates P3. Next, the third mask pattern may be removed. Each of the plurality of upper electrode plates P3 may be formed to cover a lower electrode plate P1 in a space between the plurality of intermediate electrode plates MP2. A detailed configuration and a formation method of the third conductive layer are substantially the same as those of the first conductive layer described with reference to FIG. 12A.

Referring to FIG. 12D, the upper insulating film L2 may be formed to cover the resulting product of FIG. 12C, and the first via contact VC1 and the second via contact VC2 may be formed. The first via contact VC1 may pass through a space between the plurality of upper electrode plates P3 and the space between the plurality of lower electrode plates P1, may pass through the upper insulating film L2, an intermediate electrode plate MP2, and the lower insulating film L1 (see FIGS. 3A and 3B) including the mesa portion LM in the vertical direction (Z direction), and may be in contact with the intermediate electrode plate MP2. The second via contact VC2 may pass through the space between the plurality of intermediate electrode plates MP2, may pass through the upper insulating film L2, an upper electrode plate P3, a lower electrode plate P1, and the lower insulating film L1 (see FIGS. 3A and 3B) including the mesa portion LM in the vertical direction (Z direction), and may be in contact with the upper electrode plate P3 and the lower electrode plate P1.

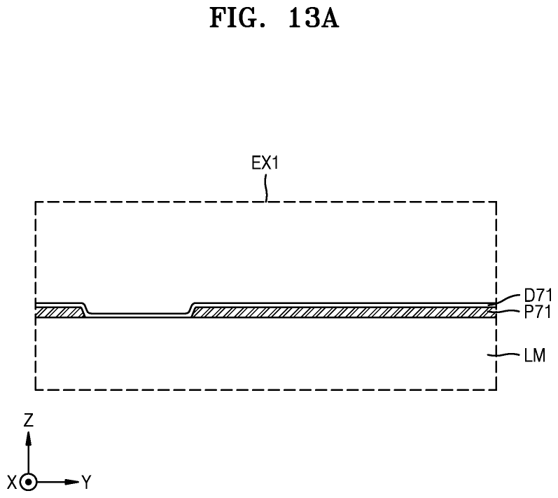

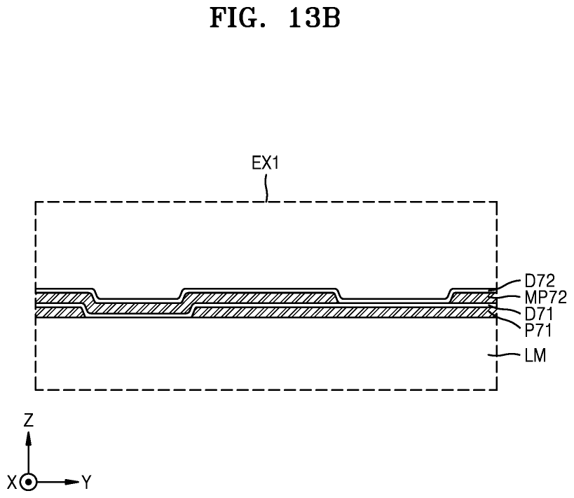

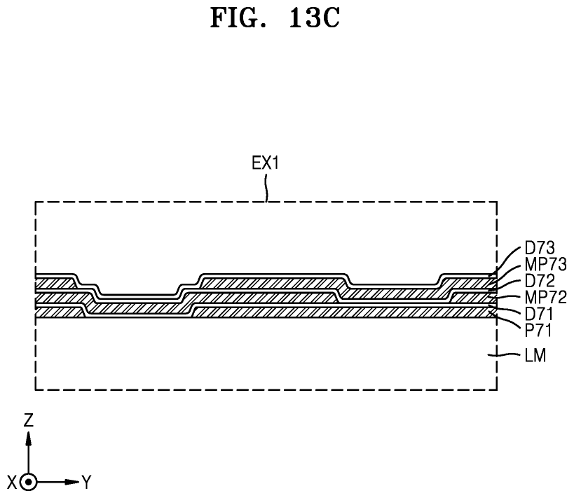

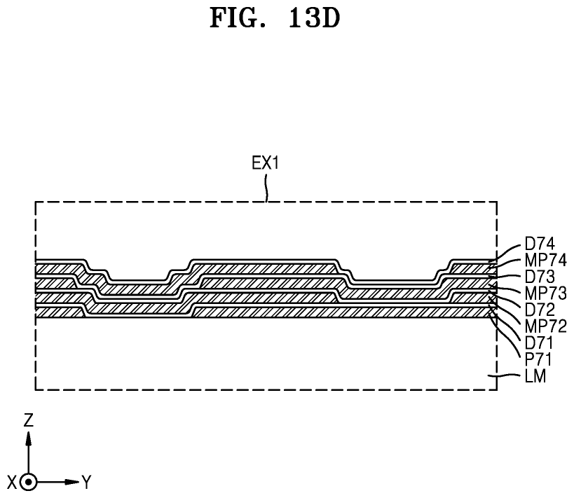

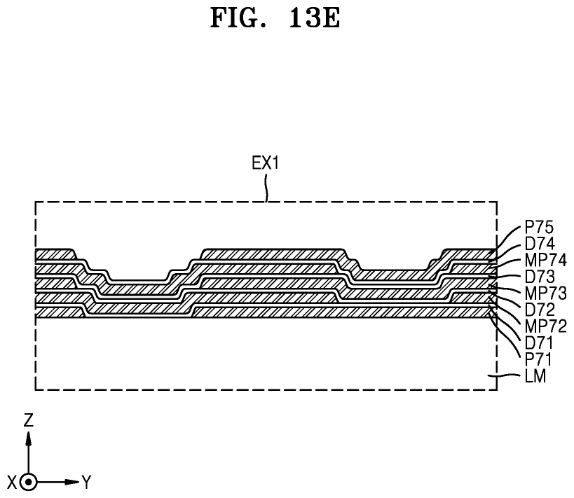

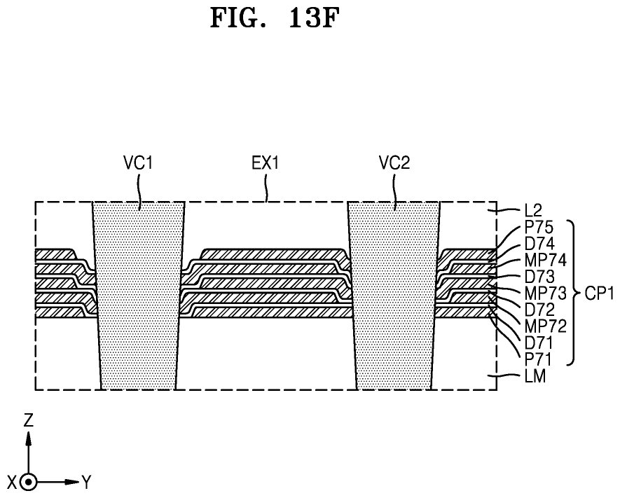

FIGS. 13A to 13F are cross-sectional views respectively illustrating a sequence of processes of an example method of fabricating the capacitor CP1 having the structure described with reference to FIG. 9. In FIGS. 13A to 13F, the same reference numerals as in FIGS. 2 and 3A to 3C respectively denote the same members, and here, repeated descriptions thereof are omitted.

Referring to FIG. 13A, by a method similar to the formation method of the plurality of lower electrode plates P1 and the dielectric film D1 as described with reference to FIG. 12A, a plurality of lower electrode plates P71 and a dielectric film D71 may be formed on the lower insulating film L1 (see FIGS. 3A and 3B) including the mesa portion LM.

Referring to FIG. 13B, by a method similar to the formation method of the plurality of intermediate electrode plates MP2 and the dielectric film D2 as described with reference to FIG. 12B, a plurality of first intermediate electrode plates MP72 and a dielectric film D72 may be formed on the resulting product of FIG. 13A. The plurality of first intermediate electrode plates MP72 and the dielectric film D72 may each be formed to cover the mesa portion LM in a space between the plurality of lower electrode plates P71.

Referring to FIG. 13C, by a method similar to the formation method of the plurality of first intermediate electrode plates MP72 and the dielectric film D72 as described with reference to FIG. 13B, a plurality of second intermediate electrode plates MP73 and a dielectric film D73 may be formed on the resulting product of FIG. 13B. The plurality of second intermediate electrode plates MP73 and the dielectric film D73 may each be formed to cover a lower electrode plate P71 in a space between the plurality of first intermediate electrode plates MP72.

Referring to FIG. 13D, by a method similar to the formation method of the plurality of first intermediate electrode plates MP72 and the dielectric film D72 as described with reference to FIG. 13B, a plurality of third intermediate electrode plates MP74 and a dielectric film D74 may be formed on the resulting product of FIG. 13C. The plurality of third intermediate electrode plates MP74 and the dielectric film D74 may each be formed to cover a first intermediate electrode plate MP72 in a space between the plurality of second intermediate electrode plates MP73.

Referring to FIG. 13E, by a method similar to the formation method of the plurality of first intermediate electrode plates MP72 and the dielectric film D72 as described with reference to FIG. 13B, a plurality of upper electrode plates P75 may be formed on the resulting product of FIG. 13D. The plurality of upper electrode plates P75 may each be formed to cover a second intermediate electrode plate MP73 in a space between the plurality of third intermediate electrode plates MP74.

Referring to FIG. 13F, the upper insulating film L2 may be formed to cover the resulting product of FIG. 13E, and the first via contact VC1 and the second via contact VC2 may be formed. The first via contact VC1 may pass through a space between the plurality of upper electrode plates P75, the space between the plurality of second intermediate electrode plates MP73, and the space between the plurality of lower electrode plates P71, may pass through the upper insulating film L2, a third intermediate electrode plates MP74, a first intermediate electrode plates MP72, and the lower insulating film L1 (see FIGS. 3A and 3B) including the mesa portion LM in the vertical direction (Z direction), and may be in contact with the third intermediate electrode plates MP74 and the first intermediate electrode plates MP72. The second via contact VC2 may pass through the space between the plurality of third intermediate electrode plates MP74 and the space between the plurality of first intermediate electrode plates MP72, may pass through the upper insulating film L2, the upper electrode plate P3, a second intermediate electrode plates MP73, the lower electrode plate P71, and the lower insulating film L1 (see FIGS. 3A and 3B) including the mesa portion LM in the vertical direction (Z direction), and may be in contact with the upper electrode plate P3, the second intermediate electrode plates MP73, and the lower electrode plate P71.

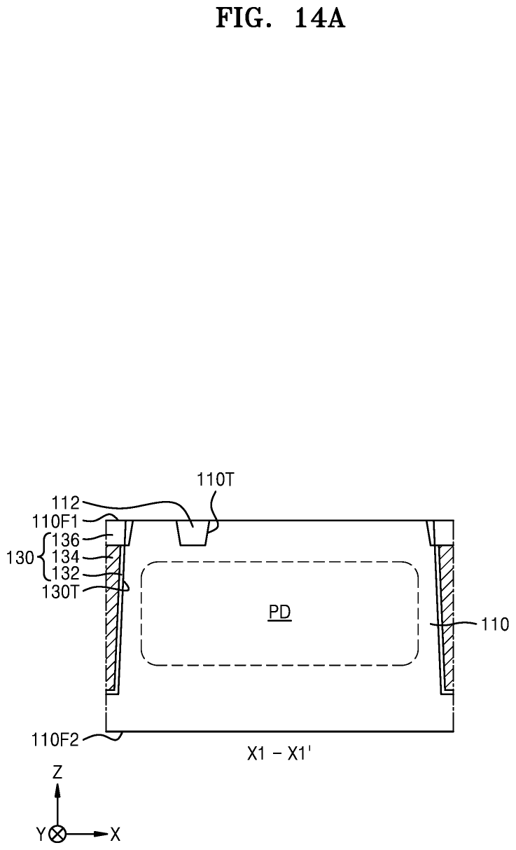

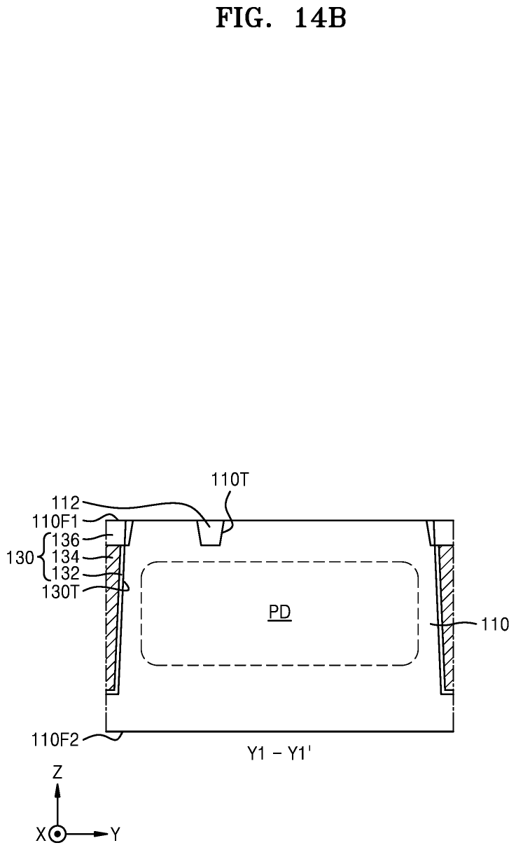

FIGS. 14A to 21B are cross-sectional views respectively illustrating a sequence of processes of an example method of fabricating an image sensor, according to some embodiments, and in particular, FIGS. 14A to 21A respectively illustrate cross-sectional views of the image sensor, which correspond to a cross-section taken along the line X1-X1′ of FIG. 11A, according to the sequence of processes, and FIGS. 14B to 21B respectively illustrate cross-sectional views of the image sensor, which correspond to a cross-section taken along the line Y1-Y1′ of FIG. 11A, according to the sequence of processes. An example of a method of fabricating the image sensor 900 shown in FIGS. 11A to 11C is described with reference to FIGS. 14A to 21B. In FIGS. 14A to 21B, the same reference numerals as in FIGS. 2, 3A to 3C, 11A, and 11C respectively denote the same members, and here, repeated descriptions thereof are omitted.

Referring to FIGS. 14A and 14B, the substrate 110 having the first surface 110F1 and the second surface 110F2, which are opposite to each other, may be prepared, and the photodiode PD may be formed by performing an ion implantation process on the first surface 110F1 of the substrate 110. The photodiode PD may include an N-type impurity region and a P-type impurity region.

A device isolation trench 110T may be formed by etching a portion of the substrate 110 from the first surface 110F1 of the substrate 110, and the device isolation film 112 may be formed in the device isolation trench 110T. Next, a pixel trench 130T may be formed by etching a portion of the device isolation film 112 and a portion of the substrate 110 from a first surface 110F1 side of the substrate 110. Next, the insulating film 132 may be formed to conformally cover an inner surface of the pixel trench 130T, and the conductive film 134 may fill a space remaining on the insulating film 132 in the pixel trench 130T. Next, an upper space of the pixel trench 130T may be prepared by removing a portion of each of the insulating film 132 and the conductive film 134 in an upper portion of the pixel trench 130T at an entrance side of the pixel trench 130T, and the upper insulating film 136 may be formed to fill the upper space of the pixel trench 130T, thereby forming the pixel device isolation film 130.

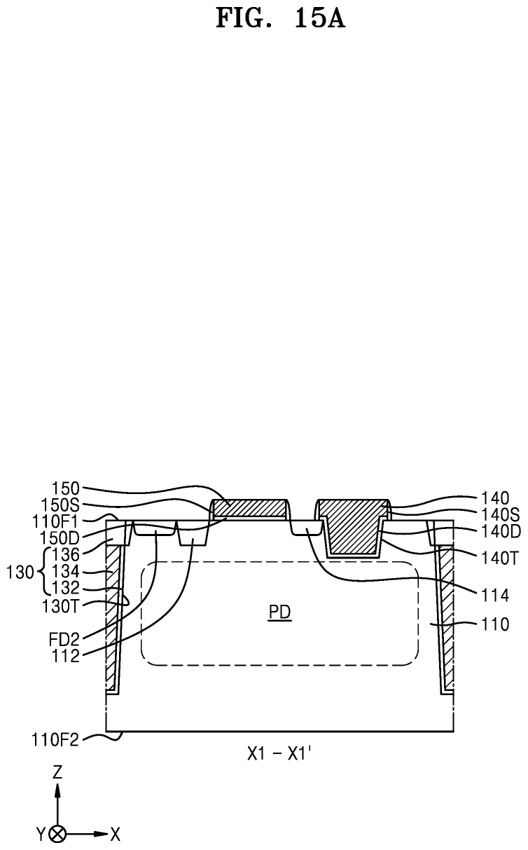

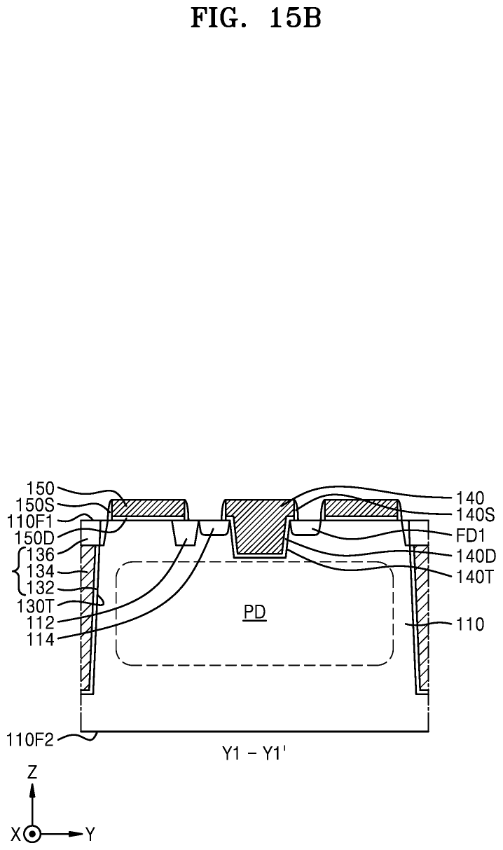

Referring to FIGS. 15A and 15B, a transfer gate trench 140T may be formed by etching a portion of the substrate 110 from the first surface 110F1 of the substrate 110. Next, a plurality of gate dielectric films 140D and 150D, the transfer gate electrode 140, and the plurality of gate electrodes 150 may be formed in the transfer gate trench 140T and on the first surface 110F1 of the substrate 110. Next, the insulating spacers 140S and 150S may be formed to cover a sidewall of the transfer gate electrode 140 and a sidewall of each of the plurality of gate electrodes 150, respectively. Next, the plurality of ion-implanted regions 114, the first floating diffusion region FD1, and the second floating diffusion region FD2 may be formed by implanting ions into portions of the substrate 110 from the first surface 110F1 of the substrate 110.

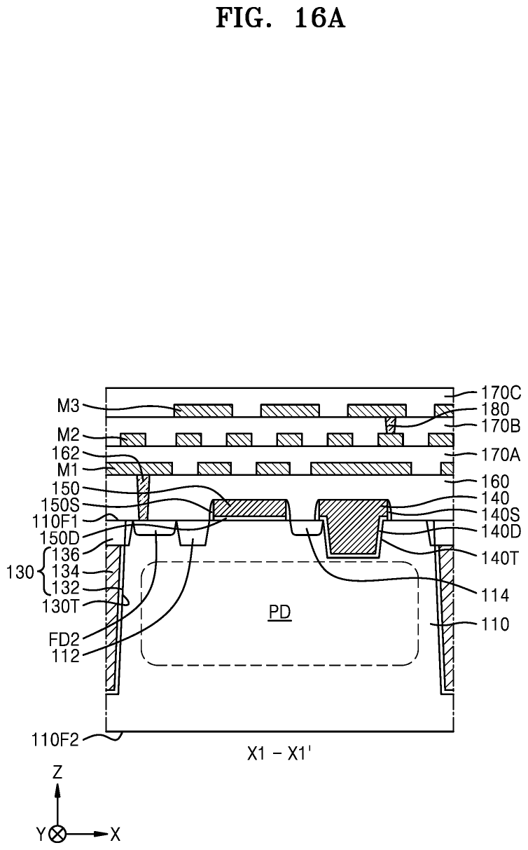

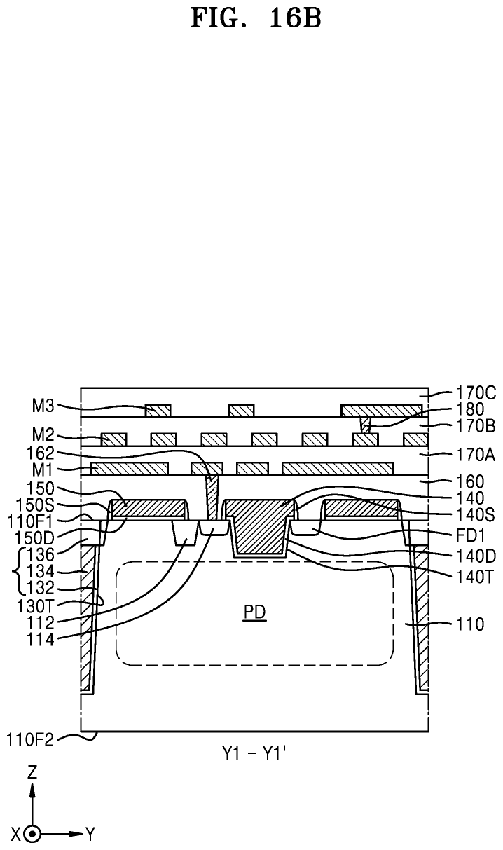

Referring to FIGS. 16A and 16B, the interlayer dielectric 160 may be formed on the first surface 110F1 of the substrate 110, and the contact plug 162 may be formed through the interlayer dielectric 160. A lower wiring structure, which includes a plurality of wiring patterns M1, M2, and M3, the plurality of contact plugs 180, and a plurality of interlayer dielectrics 170A, 170B, and 170C, may be formed on the interlayer dielectric 160.

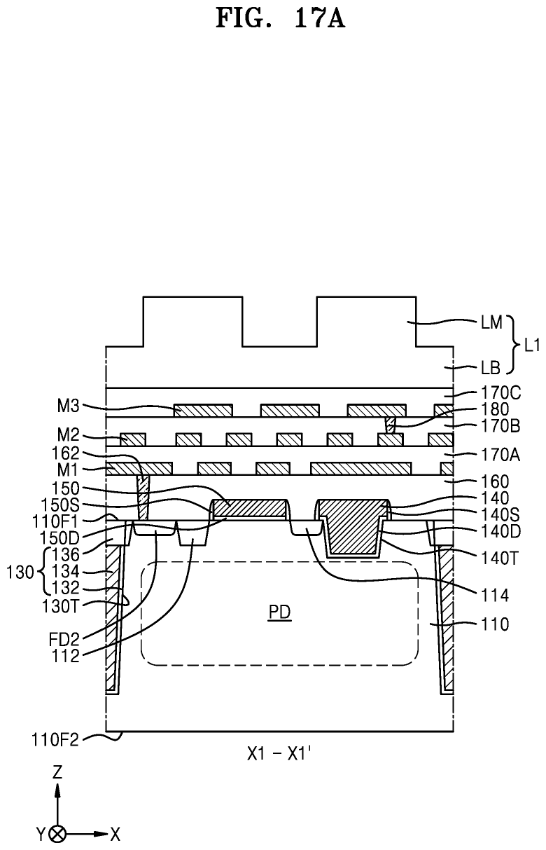

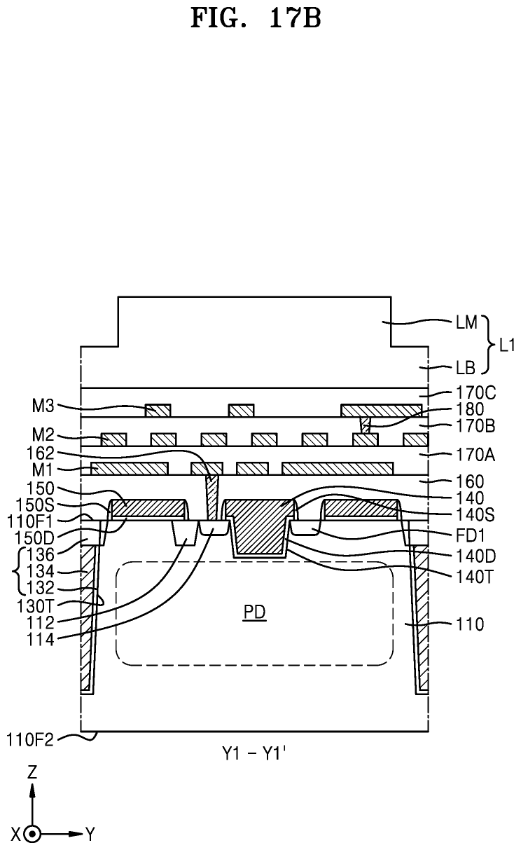

Referring to FIGS. 17A and 17B, the lower insulating film L1, which includes the base portion LB and the plurality of mesa portions LM, may be formed over the interlayer dielectric 160. In some embodiments, to form the lower insulating film L1, a preliminary lower insulating film may be formed, followed by etching the preliminary lower insulating film by as much as a certain depth from an upper surface of the preliminary lower insulating film, thereby forming the plurality of mesa portions LM. The positions of the plurality of mesa portions LM may respectively correspond to areas in which the plurality of capacitors CP1 formed in a subsequent process are arranged.

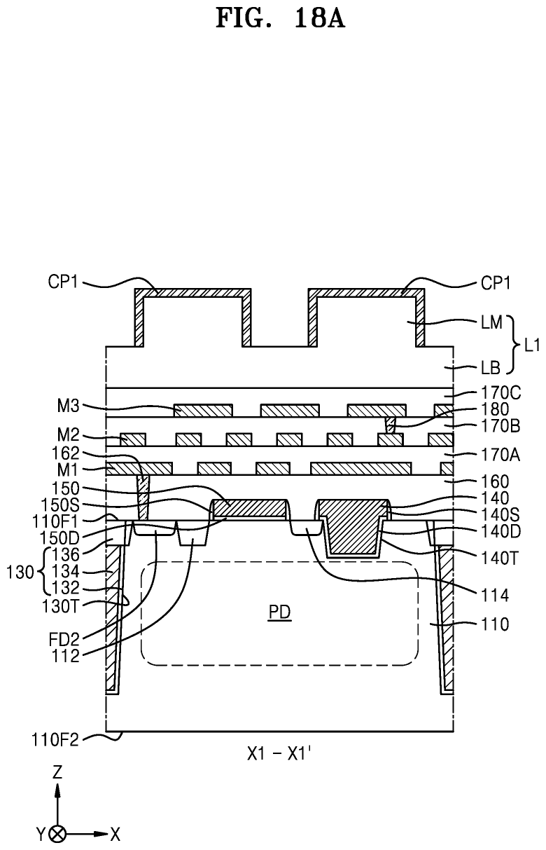

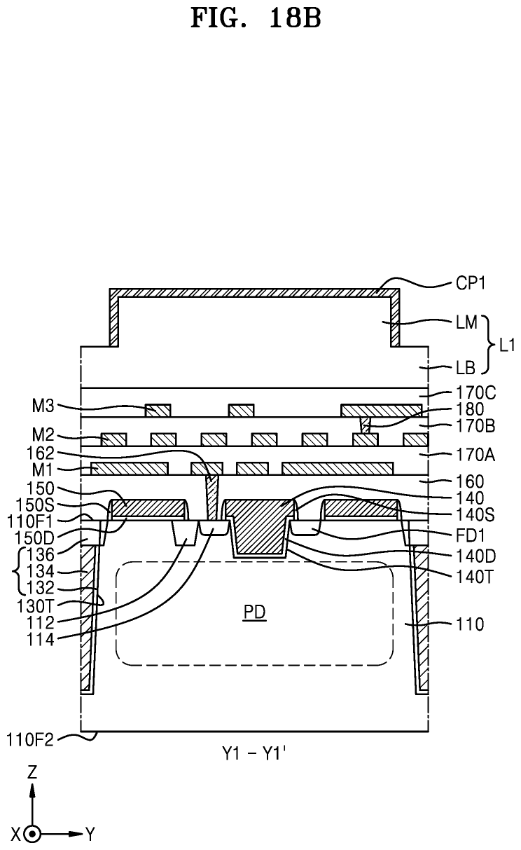

Referring to FIGS. 18A and 18B, the plurality of capacitors CP1 may be formed on the resulting product of FIGS. 17A and 17B. In some embodiments, the plurality of capacitors CP1 each having the structure shown in FIG. 3C may be formed by performing the processes described with reference to FIGS. 12A to 12D. In some embodiments, the plurality of capacitors CP1 each having the structure shown in FIG. 9 may be formed by performing the processes described with reference to FIGS. 13A to 13F.

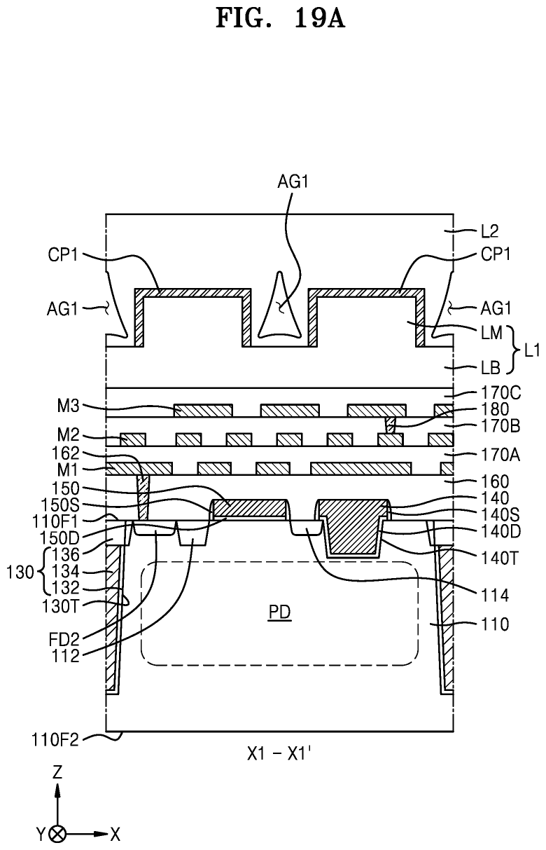

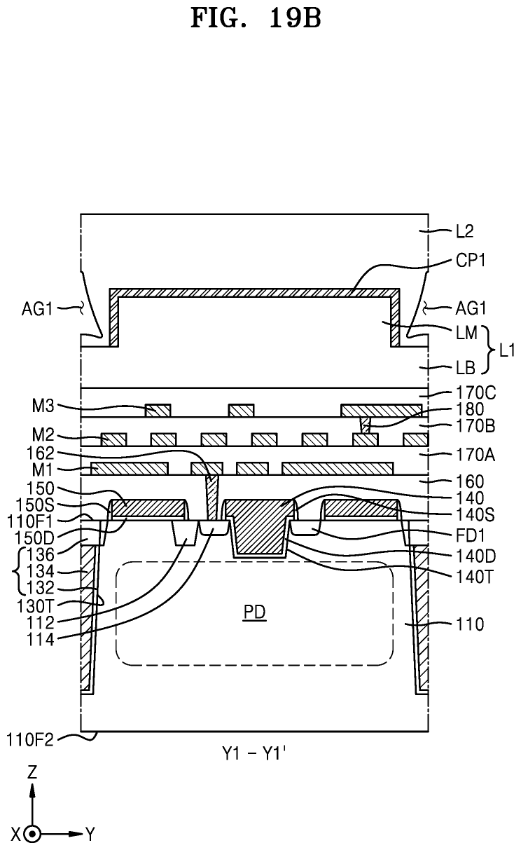

Referring to FIGS. 19A and 19B, the upper insulating film L2 may be formed on the resulting product of FIGS. 18A and 18B. To form the upper insulating film L2, a process of depositing an insulating material on the plurality of capacitors CP1 and the lower insulating film L1 may be performed by a chemical vapor deposition (CVD) process. In some embodiments, the insulating material may include or be TEOS oxide. When depositing the insulating material, by using process conditions providing relatively deteriorated step coverage, the plurality of air gaps AG1 may be respectively formed in spaces between the plurality of mesa portions LM of the lower insulating film L1 during the formation of the upper insulating film L2. Though only a cross-section is shown, in some embodiments, the air gaps may be formed to extend lengthwise in a direction in which the side wall of the adjacent mesa portion LM extends. Each air gap may extend along an entire length of an adjacent mesa portion LM side wall. An item, layer, or portion of an item or layer described as extending “lengthwise” in a particular direction has a length in the particular direction and a width perpendicular to that direction, where the length is greater than the width.

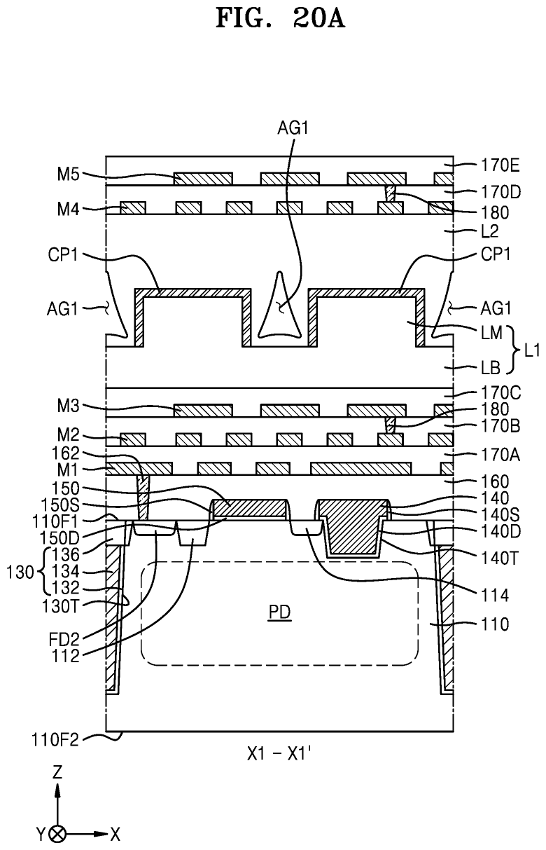

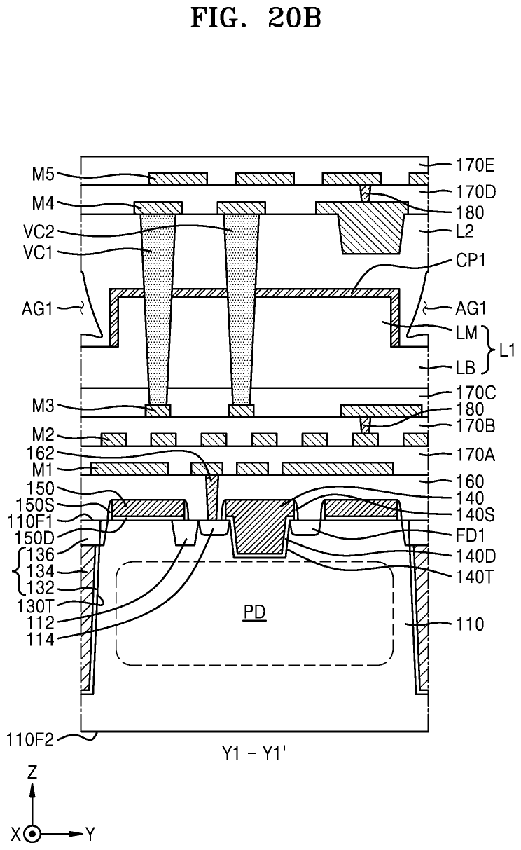

Referring to FIGS. 20A and 20B, an upper wiring structure, which includes a plurality of wiring patterns M4 and M5, the plurality of contact plugs 180, and a plurality of interlayer dielectrics 170D and 170E, may be formed on the resulting product of FIGS. 19A and 19B.

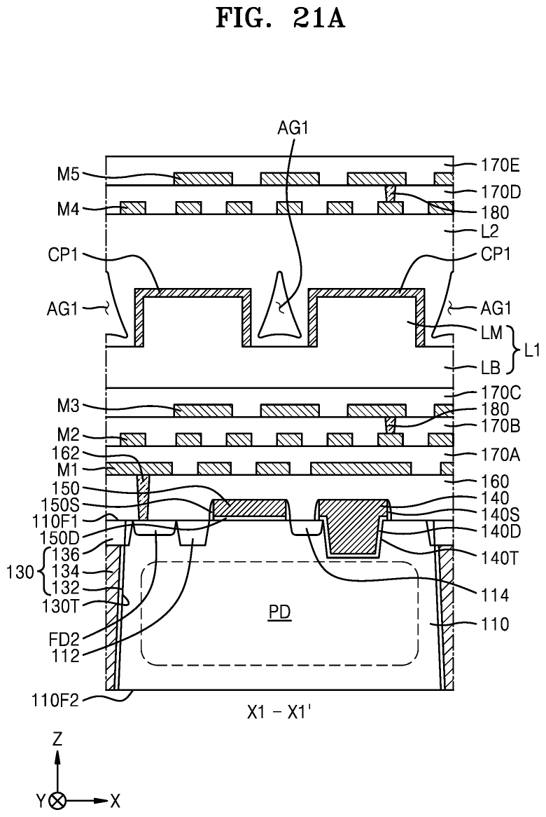

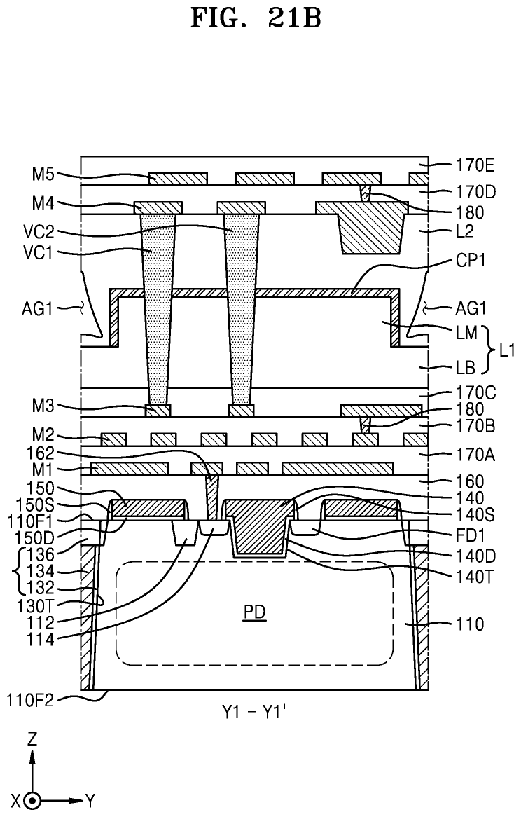

Referring to FIGS. 21A and 21B, in the resulting product of FIGS. 20A and 20B, a support substrate (not shown) may be bonded onto the structure formed on the first surface 110F1 of the substrate 110, followed by removing a portion of the substrate 110 from the second surface 110F2 of the substrate 110, thereby exposing the pixel device isolation film 130. During the removal of the portion of the substrate 110, a portion of the pixel device isolation film 130 may also be removed. To remove the portion of the substrate 110, a CMP process or an etch-back process may be used. After the portion of the substrate 110 is removed, the second surface 110F2 of the substrate 110 may be closer to the photodiode PD.

Next, as shown in FIGS. 11B and 11C, the backside insulating layer 182 may be formed on the second surface 110F2 of the substrate 110, followed by forming the passivation layer 184 on the backside insulating layer 182, and then, the color filter 186 and the micro-lens 188 may be formed on the passivation layer 184, thereby fabricating the image sensor 900 shown in FIGS. 11A to 11C.

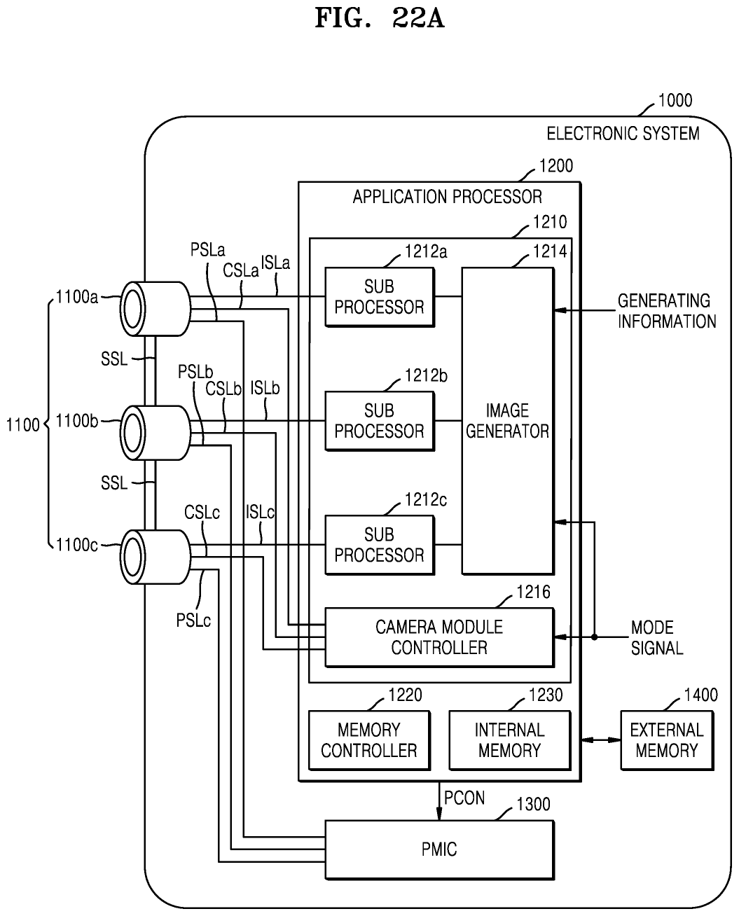

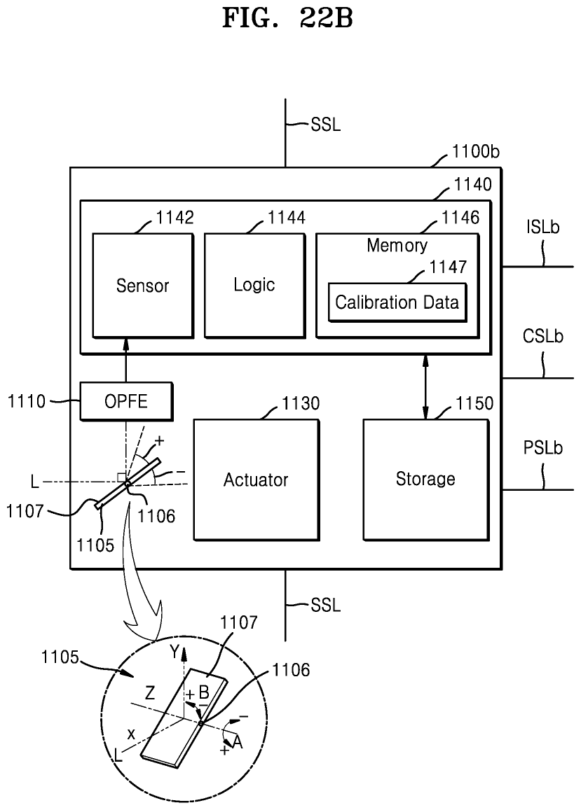

FIG. 22A is a block diagram of an electronic system 1000 according to some embodiments. FIG. 22B is a detailed block diagram of a camera module included in the electronic system 1000 of FIG. 22A.

Referring to FIG. 22A, the electronic system 1000 may include a camera module group 1100, an application processor 1200, a power management integrated circuit (PMIC) 1300, and an external memory 1400.

The camera module group 1100 may include a plurality of camera modules 1100a, 1100b, and 1100c. Although three camera modules 1100a, 1100b, and 1100c are illustrated in FIG. 22A, the inventive concept is not limited thereto. In some embodiments, the camera module group 1100 may be modified to include only two camera modules. In some embodiments, the camera module group 1100 may be modified to include “n” camera modules, where “n” is a natural number of at least 4.

The detailed configuration of the camera module 1100b will be described with reference to FIG. 22B below. The descriptions below may also be applied to the other camera modules 1100a and 1100c.

Referring to FIG. 22B, the camera module 1100b may include a prism 1105, an optical path folding element (OPFE) 1110, an actuator 1130, an image sensing device 1140, and a storage 1150.

The prism 1105 may include a reflective surface 1107 of a light reflecting material and may change the path of light L incident from outside.

In some embodiments, the prism 1105 may change the path of the light L incident in a first direction (the X direction in FIG. 22B) into a second direction (the Y direction in FIG. 22B) perpendicular to the first direction. The prism 1105 may rotate the reflective surface 1107 of the light reflecting material in a direction A around a central shaft 1106 or rotate the central shaft 1106 in a direction B to change the path of the light L incident in the first direction (the X direction) into the second direction (the Y direction) perpendicular to the first direction (the X direction). In this case, the OPFE 1110 may move in a third direction (the Z direction in FIG. 22B), which is perpendicular to the first direction (the X direction) and the second direction (the Y direction).

In some embodiments, as illustrated in FIG. 22B, an A-direction maximum rotation angle of the prism 1105 may be less than or equal to about 15 degrees in a plus (+) A direction and greater than about 15 degrees in a minus (−) A direction. However, the inventive concept is not limited thereto.

In some embodiments, the prism 1105 may move by an angle of about 20 degrees or in a range from about 10 degrees to about 20 degrees or from about 15 degrees to about 20 degrees in a plus or minus B direction. In this case, an angle by which the prism 1105 moves in the plus B direction may be the same as or similar, within a difference of about 1 degree, to an angle by which the prism 1105 moves in the minus B direction.

In some embodiments, the prism 1105 may move the reflective surface 1107 of the light reflecting material in the third direction (the Z direction) parallel with an extension direction of the central shaft 1106.

The OPFE 1110 may include, for example, “m” optical lenses, where “m” is a natural number. The “m” lenses may move in the second direction (the Y direction) and change an optical zoom ratio of the camera module 1100b. For example, when the default optical zoom ratio of the camera module 1100b is Z, the optical zoom ratio of the camera module 1100b may be changed to 3Z or 5Z or greater by moving the “m” optical lenses included in the OPFE 1110.

The actuator 1130 may move the OPFE 1110 or an optical lens to a certain position. For example, the actuator 1130 may adjust the position of the optical lens such that an image sensor 1142 is positioned at a focal length of the optical lens for accurate sensing.

The image sensing device 1140 may include the image sensor 1142, a control logic 1144, and a memory 1146. The image sensor 1142 may sense an image of an object using the light L provided through the optical lens. The control logic 1144 may control all operations of the camera module 1100b. For example, the control logic 1144 may control operation of the camera module 1100b according to a control signal provided through a control signal line CSLb.

The memory 1146 may store information, such as calibration data 1147, utilized for the operation of the camera module 1100b. The calibration data 1147 may include information, which is utilized for the camera module 1100b, to generate image data using the light L provided from outside. For example, the calibration data 1147 may include information about the degree of rotation, information about a focal length, information about an optical axis, or the like. When the camera module 1100b is implemented as a multi-state camera that has a focal length varying with the position of the optical lens, the calibration data 1147 may include a value of a focal length for each position (or state) of the optical lens and information about auto focusing.

The storage 1150 may store image data sensed by the image sensor 1142. The storage 1150 may be provided outside the image sensing device 1140 and may form a stack with a sensor chip of the image sensing device 1140. In some embodiments, although the storage 1150 may include electrically erasable programmable read-only memory (EEPROM), the inventive concept is not limited thereto.

The image sensor 1142 may include the image sensor 100, 200, 300, 400, 500, 600, 700, 800A, 800B, or 900 described with reference to FIGS. 1 to 11c, or an image sensor variously modified and changed therefrom within the scope of the inventive concept.

Referring to FIGS. 22A and 22B, in some embodiments, each of the camera modules 1100a, 1100b, and 1100c may include the actuator 1130. Accordingly, the camera modules 1100a, 1100b, and 1100c may include the calibration data 1147, which is the same or different among the camera modules 1100a, 1100b, and 1100c according to the operation of the actuator 1130 included in each of the camera modules 1100a, 1100b, and 1100c.

In some embodiments, one (e.g., the camera module 1100b) of the camera modules 1100a, 1100b, and 1100c may be of a folded-lens type including the prism 1105 and the OPFE 1110, while the other camera modules (e.g., the camera modules 1100a and 1100c) may be of a vertical type that does not include the prism 1105 and the OPFE 1110. However, the inventive concept is not limited thereto.

In some embodiments, one (e.g., the camera module 1100c) of the camera modules 1100a, 1100b, and 1100c may include a vertical depth camera, which extracts depth information using an infrared (IR) ray. In this case, the application processor 1200 may generate a three-dimensional (3D) depth image by merging image data provided from the depth camera with image data provided from another camera module (e.g., the camera module 1100a or 1100b).

In some embodiments, at least two camera modules (e.g., 1100a and 1100b) among the camera modules 1100a, 1100b, and 1100c may have different field-of-views. In this case, for example, the two camera modules (e.g., 1100a and 1100b) among the camera modules 1100a, 1100b, and 1100c may respectively have different optical lenses. However, the inventive concept is not limited thereto.

In some embodiments, the camera modules 1100a, 1100b, and 1100c may have different field-of-views from one another. In this case, although the camera modules 1100a, 1100b, and 1100c may respectively have different optical lenses, the inventive concept is not limited thereto.

In some embodiments, the camera modules 1100a, 1100b, and 1100c may be physically separated from one another. In other words, the sensing region of the image sensor 1142 is not divided and used by the camera modules 1100a, 1100b, and 1100c, but the image sensor 1142 may be independently included in each of the camera modules 1100a, 1100b, and 1100c.

Referring back to FIG. 22A, the application processor 1200 may include an image processing unit 1210, a memory controller 1220, and an internal memory 1230. The application processor 1200 may be separately implemented from the camera modules 1100a, 1100b, and 1100c. For example, the application processor 1200 and the camera modules 1100a, 1100b, and 1100c may be implemented in different semiconductor chips.

The image processing unit 1210 may include a plurality of sub-processors 1212a, 1212b, and 1212c, an image generator 1214, and a camera module controller 1216. The image processing unit 1210 may include as many sub-processors 1212a, 1212b, and 1212c as the camera modules 1100a, 1100b, and 1100c.

Pieces of image data respectively generated by the camera modules 1100a, 1100b, and 1100c may be respectively provided to the sub-processors 1212a, 1212b, and 1212c through image signal lines ISLa, ISLb, and ISLc separated from each other. For example, image data generated by the camera module 1100a may be provided to the sub-processor 1212a through the image signal line ISLa, image data generated by the camera module 1100b may be provided to the sub-processor 1212b through the image signal line ISLb, and image data generated by the camera module 1100c may be provided to the sub-processor 1212c through the image signal line ISLc. Such image data transmission may be performed using, for example, a mobile industry processor interface (MIPI) based camera serial interface (CSI). However, the inventive concept is not limited thereto.

In some embodiments, a single sub-processor may be provided for a plurality of camera modules. For example, in an embodiment, the sub-processors 1212a and 1212c may not be separated but may be integrated into a single sub-processor, and the image data provided from the camera module 1100a or the camera module 1100c may be selected by a selection element (e.g., a multiplexer) and then provided to the integrated sub-processor.

The image data provided to each of the sub-processors 1212a, 1212b, and 1212c may be provided to the image generator 1214. The image generator 1214 may generate an output image using the image data provided from each of the sub-processors 1212a, 1212b, and 1212c according to image generation information or a mode signal.

For example, the image generator 1214 may generate the output image by merging at least portions of respective pieces of image data, which are respectively generated by the camera modules 1100a, 1100b, and 1100c having different field-of-views, according to the image generation information or the mode signal. Alternatively, the image generator 1214 may generate the output image by selecting one of pieces of image data, which are respectively generated by the camera modules 1100a, 1100b, and 1100c having different field-of-views, according to the image generation information or the mode signal.

In some embodiments, the image generation information may include a zoom signal or a zoom factor. In some embodiments, the mode signal may be based on a mode selected by a user.

When the image generation information includes a zoom signal or a zoom factor and the camera modules 1100a, 1100b, and 1100c have different field-of-views, the image generator 1214 may perform different operations according to different kinds of zoom signals. For example, when the zoom signal is a first signal, the image generator 1214 may merge image data output from the camera module 1100a and image data output from the camera module 1100c and then generate an output image by using a merged image signal and image data output from the camera module 1100b and not used for merging. When the zoom signal is a second signal that is different from the first signal, the image generator 1214 may generate an output image by selecting one of the pieces of image data respectively output from the camera modules 1100a, 1100b, and 1100c, instead of performing the merging. However, the inventive concept is not limited thereto, and a method of processing image data may be changed according to some embodiments.

In some embodiments, the image generator 1214 may receive a plurality of pieces of image data, which have different exposure times, from at least one of the sub-processors 1212a, 1212b, and 1212c, and perform high dynamic range (HDR) processing on the pieces of image data, thereby generating merged image data having an increased dynamic range.

The camera module controller 1216 may provide a control signal to each of the camera modules 1100a, 1100b, and 1100c. A control signal generated by the camera module controller 1216 may be provided to a corresponding one of the camera modules 1100a, 1100b, and 1100c through a corresponding one of control signal lines CSLa, CSLb, and CSLc, which are separated from one another.

One (e.g., the camera module 1100b) of the camera modules 1100a, 1100b, and 1100c may be designated as a master camera according to the mode signal or the image generation signal including a zoom signal, and the other camera modules (e.g., the camera modules 1100a and 1100c) may be designated as slave cameras. Such designation information may be included in a control signal and provided to each of the camera modules 1100a, 1100b, and 1100c through a corresponding one of the control signal lines CSLa, CSLb, and CSLc, which are separated from one another.

A camera module operating as a master or a slave may be changed according to a zoom factor or an operation mode signal. For example, when the field-of-view of the camera module 1100a is greater than that of the camera module 1100b and the zoom factor indicates a low zoom ratio, the camera module 1100a may operate as a master and the camera module 1100b may operate as a slave. In contrast, when the zoom factor indicates a high zoom ratio, the camera module 1100b may operate as a master and the camera module 1100a may operate as a slave.

In some embodiments, a control signal provided from the camera module controller 1216 to each of the camera modules 1100a, 1100b, and 1100c may include a sync enable signal. For example, when the camera module 1100b is a master camera and the camera module 1100a is a slave camera, the camera module controller 1216 may transmit the sync enable signal to the camera module 1100b. The camera module 1100b provided with the sync enable signal may generate a sync signal based on the sync enable signal and may provide the sync signal to the camera modules 1100a and 1100c through a sync signal line SSL. The camera modules 1100a, 1100b, and 1100c may be synchronized with the sync signal and may transmit image data to the application processor 1200.

In some embodiments, a control signal provided from the camera module controller 1216 to each of the camera modules 1100a, 1100b, and 1100c may include mode information according to the mode signal. The camera modules 1100a, 1100b, and 1100c may operate in a first operation mode or a second operation mode in relation with a sensing speed based on the mode information.

In the first operation mode, the camera modules 1100a, 1100b, and 1100c may generate an image signal at a first speed (e.g., at a first frame rate), encode the image signal at a second speed that is higher than the first speed (e.g., at a second frame rate higher than the first frame rate), and transmit an encoded image signal to the application processor 1200. In this case, the second speed may be about 30 times or less the first speed.

The application processor 1200 may store the received image signal, e.g., the encoded image signal, in the internal memory 1230 therein or the external memory 1400 outside the application processor 1200. Thereafter, the application processor 1200 may read the encoded image signal from the internal memory 1230 or the external memory 1400, decode the encoded image signal, and display image data generated based on a decoded image signal. For example, a corresponding one of the sub-processors 1212a, 1212b, and 1212c of the image processing unit 1210 may perform the decoding and may also perform image processing on the decoded image signal.

In the second operation mode, the camera modules 1100a, 1100b, and 1100c may generate an image signal at a third speed that is lower than the first speed (e.g., at a third frame rate lower than the first frame rate) and transmit the image signal to the application processor 1200. The image signal provided to the application processor 1200 may not have been encoded. The application processor 1200 may perform image processing on the image signal or store the image signal in the internal memory 1230 or the external memory 1400.

The PMIC 1300 may provide power, e.g., a power supply voltage, to each of the camera modules 1100a, 1100b, and 1100c. For example, under the control of the application processor 1200, the PMIC 1300 may provide first power to the camera module 1100a through a power signal line PSLa, second power to the camera module 1100b through a power signal line PSLb, and third power to the camera module 1100c through a power signal line PSLc.

The PMIC 1300 may generate power corresponding to each of the camera modules 1100a, 1100b, and 1100c and adjust the level of the power, in response to a power control signal PCON from the application processor 1200. The power control signal PCON may include a power adjustment signal for each operation mode of the camera modules 1100a, 1100b, and 1100c. For example, the operation mode may include a low-power mode. In this case, the power control signal PCON may include information about a camera module to operate in the low-power mode and a power level to be set. The same or different levels of power may be respectively provided to the camera modules 1100a, 1100b, and 1100c. The level of power may be dynamically changed.

While the inventive concept has been particularly shown and described with reference to embodiments thereof, it will be understood that various changes in form and details may be made therein without departing from the spirit and scope of the following claims.

What is claimed is:

1. An image sensor comprising:
a lower insulating film arranged over a substrate and having a non-flat surface that has a concave-convex shape and comprises a first surface and at least one second surface, the first surface extending in a horizontal direction that is parallel to a frontside surface of the substrate, and the at least one second surface extending from the first surface toward the substrate;
a capacitor arranged on the lower insulating film to contact the non-flat surface of the lower insulating film and conformally covering the non-flat surface of the lower insulating film along a contour of the non-flat surface of the lower insulating film;
an upper insulating film covering the capacitor and the lower insulating film; and
at least one air gap having a side facing the at least one second surface of the lower insulating film in the horizontal direction, the at least one air gap having a height, which is defined by the upper insulating film, in a vertical direction.

2. The image sensor of claim 1, further comprising a first via contact and a second via contact, which pass through the upper insulating film, the capacitor, and the lower insulating film in the vertical direction and are spaced apart from each other in the horizontal direction,
wherein the first via contact and the second via contact pass through a section of the capacitor that vertically overlaps a portion of the first surface of the lower insulating film, the portion of the first surface being spaced apart from the at least one second surface of the lower insulating film in the horizontal direction and having a flat upper surface.

3. The image sensor of claim 1, further comprising a photodiode in the substrate,
wherein the photodiode and the capacitor overlap each other in the vertical direction.

4. The image sensor of claim 1, further comprising:
a photodiode in the substrate;
at least one transistor between the photodiode and the capacitor; and
a micro-lens, which is spaced apart from the capacitor in the vertical direction with the photodiode therebetween and covers a backside surface of the substrate.

5. The image sensor of claim 1, wherein the lower insulating film comprises a mesa portion having a thickness that is greater than those of other portions of the lower insulating film,
wherein the first surface of the lower insulating film comprises an upper surface of the mesa portion, the at least one second surface of the lower insulating film comprises a sidewall of the mesa portion, and the at least one air gap comprises a first air gap having a side facing the sidewall of the mesa portion in the horizontal direction,
and wherein the first air gap is spaced apart from the sidewall of the mesa portion with the capacitor therebetween.

6. The image sensor of claim 1, wherein the lower insulating film comprises a mesa portion having a thickness that is greater than those of other portions of the lower insulating film,
wherein a trench is arranged in an upper surface of the mesa portion, the trench being recessed toward a lower surface of the lower insulating film,
wherein the first surface of the lower insulating film comprises the upper surface of the mesa portion, the at least one second surface of the lower insulating film comprises a sidewall of the mesa portion and an inner sidewall of the trench, and the at least one air gap comprises a first air gap having a side facing the sidewall of the mesa portion in the horizontal direction and a second air gap having a side facing the inner sidewall of the trench in the horizontal direction,
and wherein the second air gap overlaps the capacitor in the vertical direction and is spaced apart from the inner sidewall of the trench with the capacitor therebetween.

7. The image sensor of claim 1, wherein a trench is arranged in an upper surface of the lower insulating film, the trench being recessed toward a lower surface of the lower insulating film,
and wherein the first surface of the lower insulating film comprises the upper surface of the lower insulating film, the at least one second surface of the lower insulating film comprises an inner sidewall of the trench, and the at least one air gap comprises an air gap facing the inner sidewall of the trench in the horizontal direction.

8. The image sensor of claim 1, wherein the capacitor comprises a metal-insulator-metal (MIM) capacitor comprising a plurality of electrode plates that are sequentially stacked on the lower insulating film,
wherein the plurality of electrode plates comprise:
a lower electrode plate;
an upper electrode plate; and
at least one intermediate electrode plate between the lower electrode plate and the upper electrode plate,
and wherein the MIM capacitor further comprises a plurality of dielectric films each arranged between electrode plates adjacent to each other from among the lower electrode plate, the upper electrode plate, and the at least one intermediate electrode plate, such that the lower electrode plate, the upper electrode plate, and the at least one intermediate electrode plate are spaced apart from each other.

9. The image sensor of claim 1, further comprising a first via contact and a second via contact, which pass through the upper insulating film, the capacitor, and the lower insulating film in the vertical direction and are spaced apart from each other in the horizontal direction,
wherein the capacitor comprises:
a lower electrode plate;
an upper electrode plate;
an intermediate electrode plate between the lower electrode plate and the upper electrode plate; and
a plurality of dielectric films each arranged between electrode plates adjacent to each other from among the lower electrode plate, the upper electrode plate, and the intermediate electrode plate, such that the lower electrode plate, the upper electrode plate, and the intermediate electrode plate are spaced apart from each other,
wherein the first via contact is in contact with the lower electrode plate and the upper electrode plate and is spaced apart from the intermediate electrode plate,
and wherein the second via contact is in contact with the intermediate electrode plate and is spaced apart from the lower electrode plate and the upper electrode plate.

10. The image sensor of claim 1, further comprising a first via contact and a second via contact, which pass through the upper insulating film, the capacitor, and the lower insulating film in the vertical direction and are spaced apart from each other in the horizontal direction,
wherein the capacitor comprises:
a lower electrode plate;
an upper electrode plate;
a first intermediate electrode plate, a second intermediate electrode plate, and a third intermediate electrode plate, which are arranged between the lower electrode plate and the upper electrode plate and stacked in the stated order from the lower electrode plate toward the upper electrode plate; and
a plurality of dielectric films each arranged between electrode plates adjacent to each other from among the lower electrode plate, the upper electrode plate, the first intermediate electrode plate, the second intermediate electrode plate, and the third intermediate electrode plate, such that the lower electrode plate, the upper electrode plate, the first intermediate electrode plate, the second intermediate electrode plate, and the third intermediate electrode plate are spaced apart from each other,
wherein the first via contact is in contact with the lower electrode plate, the second intermediate electrode plate, and the upper electrode plate and is spaced apart from the first intermediate electrode plate and the third intermediate electrode plate,
and wherein the second via contact is in contact with the first intermediate electrode plate and the third intermediate electrode plate and is spaced apart from the lower electrode plate, the second intermediate electrode plate, and the upper electrode plate.

11. An image sensor comprising:
a plurality of lower wiring patterns over a substrate;
a lower insulating film covering the plurality of lower wiring patterns and having a surface that has a concave-convex shape and comprises a first surface and at least one second surface, the first surface extending in at least one of a first horizontal direction and a second horizontal direction, which are parallel to a frontside surface of the substrate, and the at least one second surface extending from the first surface toward the substrate;
at least one capacitor arranged on the lower insulating film to contact the surface of the lower insulating film, the at least one capacitor conformally covering the surface of the lower insulating film along a contour of the concave-convex shape of the surface of the lower insulating film;
an upper insulating film covering the at least one capacitor and the lower insulating film;
at least one air gap adjacent to the at least one second surface of the lower insulating film in the first horizontal direction or the second horizontal direction, the at least one air gap having a height, which is defined by the upper insulating film, in a vertical direction;
a plurality of upper wiring patterns on the upper insulating film; and
a first via contact and a second via contact, each passing through a portion of the at least one capacitor, which covers the first surface of the lower insulating film, in the vertical direction and each connected between one of the plurality of lower wiring patterns and one of the plurality of upper wiring patterns, the first via contact and the second via contact being spaced apart from each other in the second horizontal direction.

12. The image sensor of claim 11, wherein the lower insulating film comprises a mesa portion having a thickness that is greater than those of other portions of the lower insulating film,
and wherein the first surface of the lower insulating film comprises an upper surface of the mesa portion, the at least one second surface of the lower insulating film comprises a sidewall of the mesa portion, and the at least one air gap comprises a first air gap adjacent to the sidewall of the mesa portion in the first horizontal direction or the second horizontal direction.

13. The image sensor of claim 11, wherein the lower insulating film comprises a mesa portion having a thickness that is greater than those of other portions of the lower insulating film,
wherein a trench is arranged in an upper surface of the lower insulating film, the trench being recessed toward a lower surface of the lower insulating film,
and wherein the first surface of the lower insulating film comprises the upper surface of the lower insulating film, the at least one second surface of the lower insulating film comprises a sidewall of the mesa portion and an inner sidewall of the trench, and the at least one air gap comprises a first air gap adjacent to the sidewall of the mesa portion in the first horizontal direction or the second horizontal direction and a second air gap adjacent to the inner sidewall of the trench in the second horizontal direction.

14. The image sensor of claim 11, wherein a trench is arranged in an upper surface of the lower insulating film, the trench being recessed toward a lower surface of the lower insulating film,
and wherein the first surface of the lower insulating film comprises the upper surface of the lower insulating film, the at least one second surface of the lower insulating film comprises an inner sidewall of the trench, and the at least one air gap comprises an air gap adjacent to the inner sidewall of the trench in the second horizontal direction.

15. The image sensor of claim 11, wherein the at least one capacitor comprises a metal-insulator-metal (MIM) capacitor comprising a plurality of electrode plates that are sequentially stacked on the lower insulating film,
wherein the plurality of electrode plates comprise:
a lower electrode plate;
an upper electrode plate; and
at least one intermediate electrode plate between the lower electrode plate and the upper electrode plate,
and wherein the MIM capacitor further comprises a plurality of dielectric films each arranged between electrode plates adjacent to each other from among the lower electrode plate, the upper electrode plate, and the at least one intermediate electrode plate, such that the lower electrode plate, the upper electrode plate, and the at least one intermediate electrode plate are spaced apart from each other.

16. The image sensor of claim 11, wherein the at least one capacitor comprises:
a lower electrode plate;
an upper electrode plate;
an intermediate electrode plate between the lower electrode plate and the upper electrode plate; and
a plurality of dielectric films each arranged between electrode plates adjacent to each other from among the lower electrode plate, the upper electrode plate, and the intermediate electrode plate, such that the lower electrode plate, the upper electrode plate, and the intermediate electrode plate are spaced apart from each other,
wherein the first via contact is in contact with the lower electrode plate and the upper electrode plate and is spaced apart from the intermediate electrode plate,
and wherein the second via contact is in contact with the intermediate electrode plate and is spaced apart from the lower electrode plate and the upper electrode plate.

17. The image sensor of claim 11, wherein the at least one capacitor comprises:
a lower electrode plate;
an upper electrode plate;
a first intermediate electrode plate, a second intermediate electrode plate, and a third intermediate electrode plate, which are arranged between the lower electrode plate and the upper electrode plate and stacked in the stated order from the lower electrode plate toward the upper electrode plate; and
a plurality of dielectric films each arranged between electrode plates adjacent to each other from among the lower electrode plate, the upper electrode plate, the first intermediate electrode plate, the second intermediate electrode plate, and the third intermediate electrode plate, such that the lower electrode plate, the upper electrode plate, the first intermediate electrode plate, the second intermediate electrode plate, and the third intermediate electrode plate are spaced apart from each other,
wherein the first via contact is in contact with the lower electrode plate, the second intermediate electrode plate, and the upper electrode plate and is spaced apart from the first intermediate electrode plate and the third intermediate electrode plate,
and wherein the second via contact is in contact with the first intermediate electrode plate and the third intermediate electrode plate and is spaced apart from the lower electrode plate, the second intermediate electrode plate, and the upper electrode plate.

18. The image sensor of claim 11, further comprising a plurality of photodiodes in the substrate,
wherein the at least one capacitor comprises a plurality of capacitors, which are arranged over the substrate and respectively overlap the plurality of photodiodes in the vertical direction, and
the plurality of capacitors are arranged at regular pitches in the first horizontal direction and the second horizontal direction.

19. The image sensor of claim 11, further comprising a plurality of photodiodes in the substrate,
wherein the at least one capacitor comprises a plurality of capacitors, which are arranged over the substrate and respectively overlap the plurality of photodiodes in the vertical direction, and
the plurality of capacitors comprise sets of two capacitors, wherein set of two capacitors overlaps one photodiode selected from the plurality of photodiodes in the vertical direction and are includes two capacitors spaced apart from each other in the first horizontal direction.

20. An electronic system comprising:
at least one camera module comprising an image sensor; and
a processor configured to process image data received from the at least one camera module,
wherein the image sensor comprises:
a lower insulating film arranged over a substrate and having a surface that has a concave-convex shape and comprises a first surface and at least one second surface, the first surface extending in a horizontal direction that is parallel to a frontside surface of the substrate, and the at least one second surface extending from the first surface toward the substrate;
a capacitor arranged on the lower insulating film to contact the surface of the lower insulating film and conformally covering the surface of the lower insulating film along a contour of the concave-convex shape of the surface of the lower insulating film;
an upper insulating film covering the capacitor and the lower insulating film; and
at least one air gap having a side facing the at least one second surface of the lower insulating film in the horizontal direction, the at least one air gap formed in the upper insulating film.
